(19) United States
(12) Patent Application Publication
(10) Pub. No.: US 2016/0269828 A1
(43) Pub. Date: Sep. 15, 2016

(54) METHOD FOR REDUCING LOUDSPEAKER PHASE DISTORTION

(71) Applicant: LINN PRODUCTS LIMITED, Glasgow (GB)

(72) Inventors: Murray SMITH, Glasgow (GB); Philip BUDD, Glasgow (GB); Keith ROBERTSON, Glasgow (GB)

(21) Appl. No.: 15/031,477

(22) PCT Filed: Oct. 24, 2014
(86) PCT No.: PCT/GB2014/053176

§ 371 Date: Apr. 22, 2016

(30) Foreign Application Priority Data
Oct. 24, 2013 (GB) 1318802.4

(51) Int. Cl. H04R 3/14; H03H 21/00; H04R 3/04

(52) U.S. Cl. CPC H04R 3/14; H04R 3/04; H03H 21/0012; H04R 2499/11

(57) ABSTRACT

A method for reducing loudspeaker magnitude and/or phase distortion, in which one or more filters pertaining to one or more drive units is automatically generated or modified based on the response of each specific drive unit. The drive unit response may be determined by electromechanical modelling of the drive unit. Drive unit models may be enhanced by electromechanical and/or acoustic measurement such that the resulting filter becomes specific to each specific drive unit.

### BACKGROUND OF THE INVENTION

1. Field of the Invention

The invention eliminates phase distortion in electronic crossovers and loudspeaker drive units. It may be used in software upgradable loudspeakers.

2. Description of the Prior Art

Phase Distortion in Analogue Loudspeakers

Phase distortion can be considered as any frequency dependent phase response; that is the phase angle of a system that differs at any discrete frequency when compared to the phase angle at another discrete frequency. Only a system whose phase delay is identical at all frequencies can be said to be linear phase.

All analogue loudspeakers, both traditional passive systems and actively amplified systems, introduce phase distortion. FIG. 1 shows the magnitude and phase response of a 6″ full-range driver mounted in a sealed enclosure. It is clear that this does not provide a system which is immune to phase distortion. Throughout the pass-band of the drive unit the phase response varies by more than 200 degrees. It should be noted the enclosure volume in this example is rather small and over damped for the drive unit, if the volume were increased and the damping reduced the low frequency phase response will tend towards 180 degrees, as theoretically expected. At higher frequencies the phase response will asymptote to −90 degrees.

An analogue crossover will also introduce phase distortion, often described by the related group delay, of 45 degrees per order of filter applied at the crossover frequency, and a total of 90 degrees over the full bandwidth. FIG. 2 shows the response of the same full-range drive unit now band limited by fourth order Linkwitz-Riley crossovers at 100 Hz and 1 kHz. As expected the phase distortion is now more pronounced.

The phase distortion depicted in FIGS. 1 and 2 manifests itself as a frequency dependent delay, or group delay, the low frequencies being delayed relative to the higher frequencies.

The influence of the phase distortion introduced by the drive unit is easily observed if we consider the effect when a square wave is passed through the drive unit (and crossover). A square wave can be mathematically described as the combination of a sine wave at a given fundamental frequency with harmonically related sinusoids of lower amplitude, as defined in equation 1.

$$f ( t ) = {\sum }_{n = 1 , 3 , 5 , …}^{∞} \frac{1}{n} sin ( n 2 π ft ) . \qquad Eq . 1$$

FIG. 3 shows the first 5 contributing sinusoids of a square wave, along with their summed response. As more harmonics are added the summation approaches a true square. It is important to note that all of the sinusoids have the identical phase responses; they all start at zero and are rising.

If the sinusoids are not of identical phase the summed result will no longer produce a square wave. If we apply the phase error (ignoring the magnitude response) present in the full range driver system depicted in FIG. 1 we can see the impact of phase distortion quite clearly. FIG. 4 shows a 200 Hz square wave reproduced using the full range drive unit in its sealed enclosure.

If we now consider a typical multi-way loudspeaker system with separate low and high frequency drive units and their appropriate crossover filters we can further examine the impact of phase distortion on playback. The traces presented in FIG. 5 show the magnitude and phase response of a coaxial driver system (the tweeter is mounted in the centre of the bass driver). The woofer and tweeter are joined with a fourth order crossover ensuring a true phase connection of both transducers.

Applying the phase response of the system (the heavy dash-dot line) of FIG. 5, again ignoring the magnitude response, we see the result on the square wave (FIG. 6).

While square waves are not typically found in music signals, analysis of the square provides useful graphical insight into the problem of phase distortion in audio playback. Any musical sound, a piano note for example, contains a fundamental frequency combined with harmonics. The relationship in both magnitude and phase of fundamental and its harmonics are essential to the correct reproduction of the piano note. The current state of the art in analogue loudspeakers is unable to accurately reproduce the true magnitude and phase response of a complex signal.

### Phase Correction

### Time Alignment

Prior art in correcting for phase distortion in passive loudspeakers has generally focussed on the group delay associated with the physical offsets of the drive units. If all drive units in a multi-way system are mounted on the same vertical baffle the acoustic centres of the drive units will not be flush with the loudspeaker baffle. Bass driver units will have their acoustic centre behind the baffle at the face of the cone, tweeters or other dome units will have their centres forward of the baffle.

Many manufacturers have chosen to angle the baffle of the loudspeaker backwards to align the acoustic centres of the drive units (in the vertical plane). Other manufacturers have added phase delay networks to provide a small amount of delay to the high frequency units to provide better time alignment with the low frequency drive units.

Neither approach actually eliminates the phase distortion associated with either crossover or the drive units themselves.

### Linear Phase Passive Crossovers

Despite many claims there is little evidence that a true linear phase passive crossover exists. Often first order crossover networks are quoted as being linear phase. The electrical magnitude and phase response of a first order crossover is shown in FIG. 7.

FIG. 7 shows that a first order crossover, considered in isolation, does sum to zero phase. However, when one considers the response of a drive unit, such as the one in FIG. 1, in addition to that of the first order crossover, it is clear that the result of the overall speaker system is no longer zero phase. The traces shown in FIG. 7 are the electrical response of the crossover. When these are coupled to the complex reactive load of a drive unit of FIG. 1, significant variation from this ideal is to be expected. With the gentle 6 dB per octave slope it is inevitable that the natural second order roll-on of the high frequency drive unit will influence the claimed first order characteristic of the crossover breaking the linear phase relationship shown in FIG. 7. Further problems arise in the final loudspeaker system using 1^{st} order crossovers as the individual phase of the high and low pass sections are in phase quadrature, they have a constant difference of 90 degrees, causing unfavourable lobing from the final loudspeaker system.

### Digital Crossovers

Digital crossover filters, and in particular finite impulse response (FIR) filters, are capable of arbitrary phase response and would seem to offer the ideal solution to phase distortion. However, the method used to achieve this compensation is not always optimal. Most existing compensation techniques use an acoustic measurement to determine the drive-unit impulse response. The acoustic response of a loudspeaker is complex and 3-dimensional and cannot be represented fully by a single measurement, or even by an averaged series of measurements. Indeed, correcting for the acoustic response at one measurement point may well make the response worse at other points, thus defeating the object of the correction process.

### SUMMARY OF THE INVENTION

The invention is a method for reducing loudspeaker magnitude and/or phase distortion, in which one or more filters pertaining to one or more drive units is automatically generated or modified based on the response of each specific drive unit.

Optional features in an implementation of the invention include any one or more of the following:
the drive unit response is determined by modelling the drive unit.
the drive unit response is determined by electro-mechanical modelling of the drive unit.
the electro-mechanical modelling is enhanced by electro-mechanical measurement of a specific drive unit such that the resulting filter becomes specific to that drive unit.
the electro-mechanical modelling of the drive unit is defined using any one or more of the parameters fₛ, Q_{TS}, R_{E}, Lₑ or L_{VC}
the drive unit response is determined by acoustic modelling of the drive unit.
the modelling incorporates any electronic passive filtering in front of the drive unit.
The modelling is enhanced by electro-mechanical measurement of the passive filtering in front of each drive unit.
the electro-mechanical modelling is enhanced by the use of acoustic measurements of a specific drive unit.
the filter is automatically generated or modified using a software tool or system based on the above modelling the filter is implemented using a digital filter, such as a FIR filter.
the filter incorporates a band limiting filter, such as a crossover filter, such that the resulting filter exhibits minimal or zero magnitude and/or phase distortion when combined with the drive unit response.
the filter incorporates an equalisation filter such that the resulting filter exhibits minimal or zero magnitude and/or phase distortion when combined with the drive unit response.
the filter is performed prior to a passive crossover such that the filter, when combined with the passive crossover and the drive unit response reduces the magnitude and/or phase distortion of the overall system.
the filter is performed prior to an active crossover such that the filter, when combined with the passive crossover and the drive unit response reduces the magnitude and/or phase distortion of the overall system.
the drive unit model is derived from an electrical impedance measurement.
the drive unit model is enhanced by a sound pressure level measurement.
the filter operates such that the signal sent to each drive unit is delayed such that the instantaneous sound from each of the multiple drive units arrives coincidently at the listening position.
the modelling data, or data derived from the modelling of a drive unit(s), is stored locally, such as in the non-volatile memory of the speaker.
the modelling data, or data derived from the modelling of a drive unit(s), is stored in another part of the music system, but not the speaker, in the home.
the modelling data, or data derived from the modelling of a drive unit(s), is stored remotely from the music system, such as in the cloud.
if the drive unit is replaced, then the filter is updated to use the modelling data for the replacement drive unit.
the filter is updatable, for example with an improved drive unit model or measurement data.
the response of a drive unit for the loudspeaker are measured whilst in operation and the filter is regularly or continuously updated, for example in real-time or when the system is not playing, to take into account electro-mechanical variations, for example associated with variations in operating temperature.
the volume controls are implemented in the digital domain, after the filter, such that the filter precision is maximised.

Other aspects include the following:

A first aspect is a loudspeaker including one or more filters each pertaining to one or more drive units, in which the filter is automatically generated or modified based on the response of each specific drive unit.

The loudspeaker may include a filter automatically generated or modified using any one or more of the features defined above.

A second aspect is a media output device, such as a smartphone, tablet, home computer, games console, home entertainment system, automotive entertainment system, or headphones, comprising at least one loudspeaker including one or more filters each pertaining to one or more drive units, in which the filter is automatically generated or modified based on the response of each specific drive unit.

The media output device may include a filter automatically generated or modified using any one or more of the features defined above.

A third aspect is a software-implemented tool that enables a loudspeaker to be designed, the loudspeaker including one or more filters each pertaining to one or more drive units, in which the tool or system enables the filter to be automatically generated or modified based on the response of each specific drive unit.

The software implemented tool or system may enable the filter to be automatically generated or modified using any one or more of the features defined above.

A fourth aspect is a media streaming platform or system which streams media, such as music and/or video, to networked media output devices, such as smartphones, tablets, home computers, games consoles, home entertainment systems, automotive entertainment systems, and headphones, in which the platform enables the acoustic performance of the loudspeakers in specific output devices to be improved by minimizing their phase distortion, by enabling one or more filters each pertaining to one or more drive units to be automatically generated or modified based on the response of each specific drive unit, or for those filters to be used.

The media streaming platform or system includes one or more filters automatically generated or modified using any one or more of the features defined above.

A fifth aspect is a method of designing a loudspeaker, comprising the step of using the measured natural characteristics of a specific drive unit.

The measured characteristics include the impedance of a specific drive unit and/or the sound pressure level (SPL) of a specific drive unit.

The method can alternatively comprise the step of using the measured natural characteristics of a specific type or class of drive units, rather than the specific drive unit itself.

The method can further comprise automatically generating or modifying a filter using any one or more of the features defined above.

### BRIEF DESCRIPTION OF THE FIGURES

FIG. 1 shows a simulated response of a full-range drive unit in a sealed enclosure.

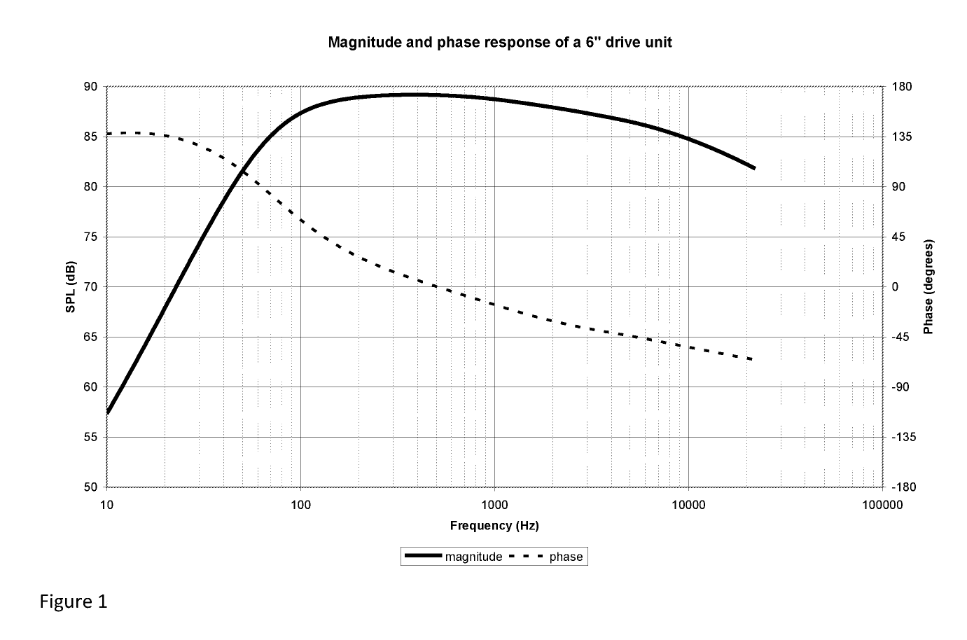

FIG. 2 shows the system from FIG. 1 with a band limiting crossover.

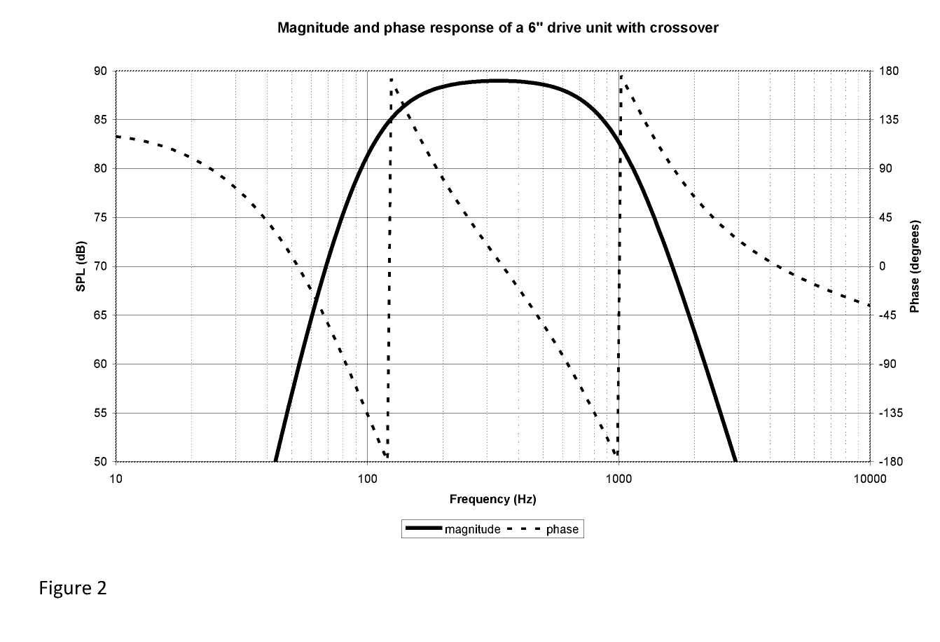

FIG. 3 shows a Fourier decomposition of a square wave.

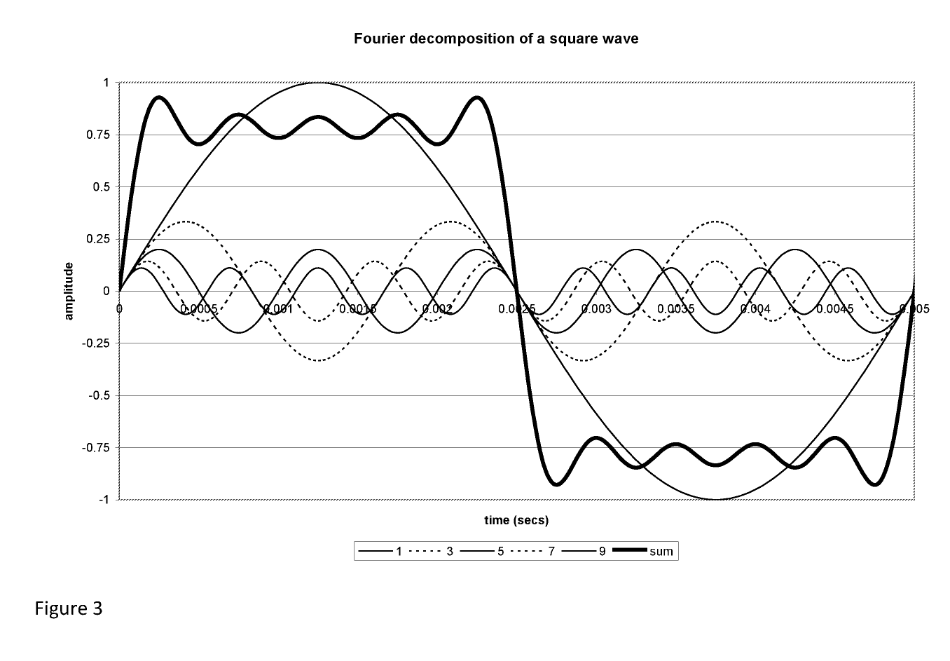

FIG. 4 shows a phase related distortion introduced by a full-range drive unit in a sealed enclosure.

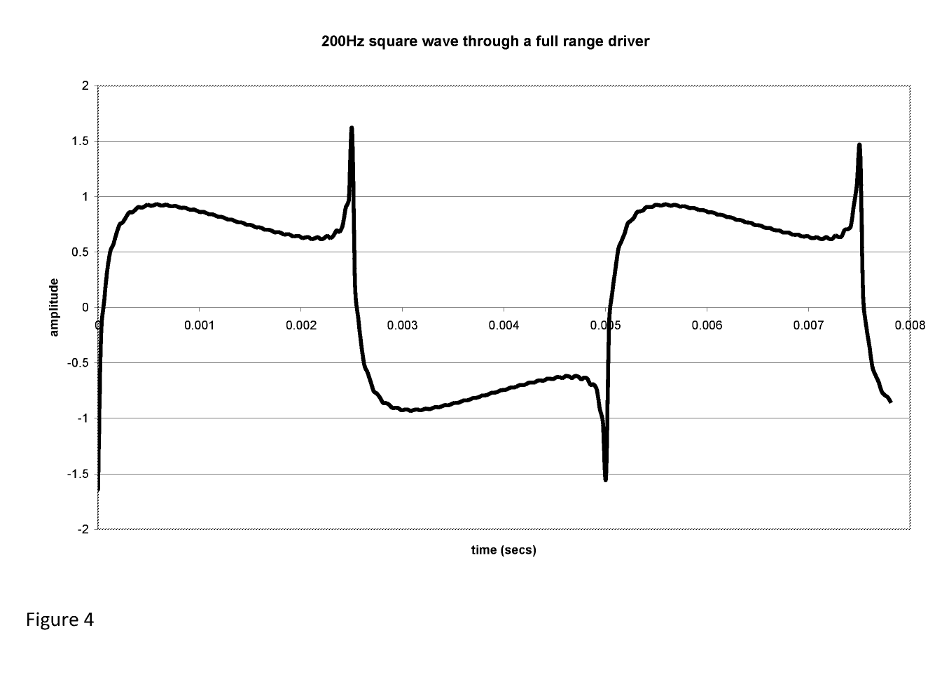

FIG. 5 shows a system response of a two-way coaxial drive unit system in a vented enclosure.

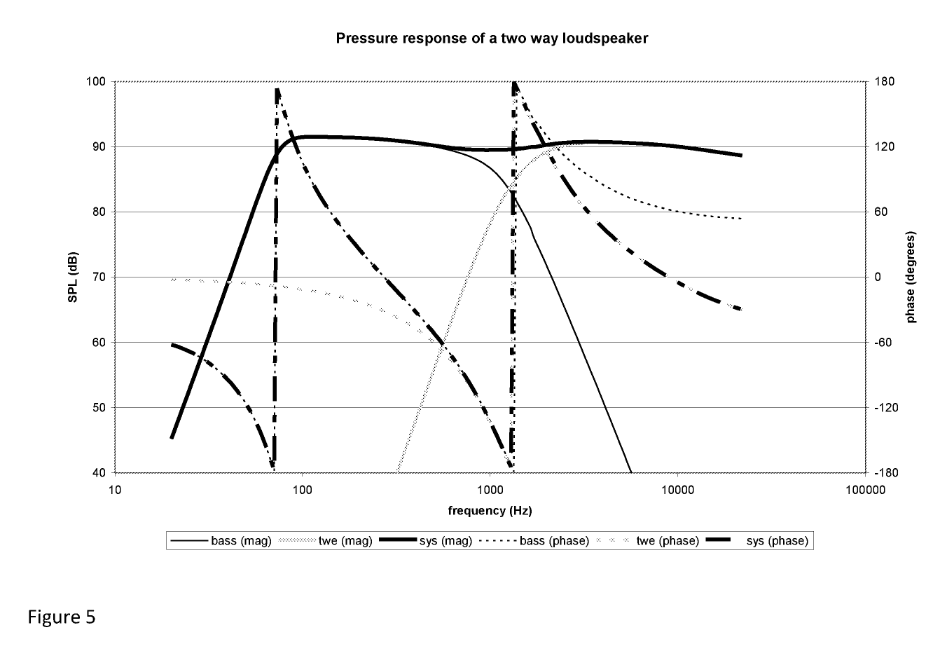

FIG. 6 shows a square wave response of the two-way coaxial drive unit system.

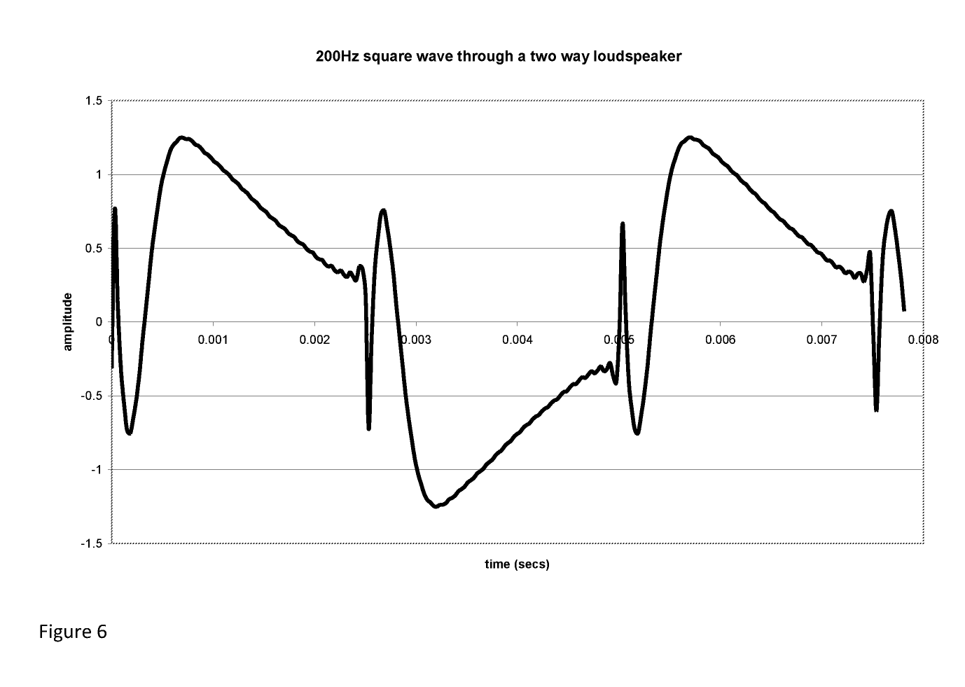

FIG. 7 shows a response of a first order analogue crossover.

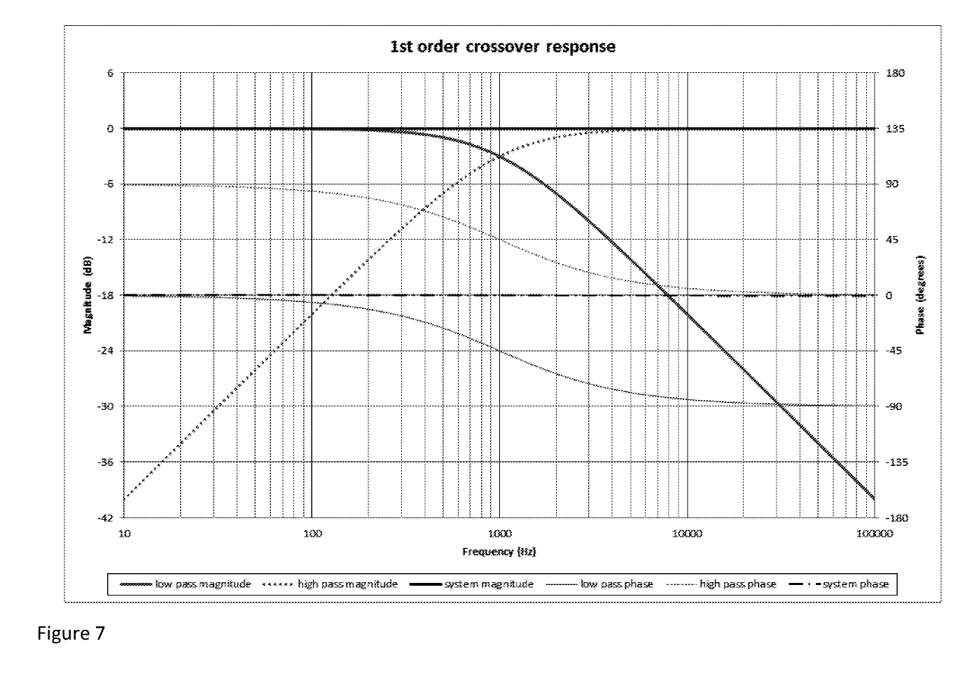

FIG. 8 shows an example of drive unit input impedance.

In Appendix 1:

FIG. 9 is a schematic of a conventional digital loudspeaker system

FIG. 10 shows a conventional digital audio signal The following Figures relate to implementations of the Appendix 1 concept:

FIG. 11 is a schematic for an architecture

FIG. 12 shows the reversed audio data flow

FIG. 13 shows wiring configurations

FIG. 14 shows daisy-chain re-clocking

FIG. 15 shows a 100Base-TX master interface

FIG. 16 shows a timing channel sync. pattern

FIG. 17 shows a data frame

FIG. 18 shows a 100Base-TX Slave Interface

FIG. 19 shows the index comparison decision logic

### DETAILED DESCRIPTION

One implementation of the invention is a system for intelligent, connected software upgradable loudspeakers. The system eliminates phase distortion in electronic crossovers and the model of loudspeaker drive units, and eliminates timing errors in multi-way loudspeakers. Correction of phase distortion from the drive unit is done on a per drive unit basis allowing for elimination of production variance for a given drive unit. The individual drive unit data can be stored in the speaker, in the music system, or in the cloud.

Key features of an implementation include the following:
1. Elimination of phase distortion from the crossover and drive units in a loudspeaker system.
   All loudspeaker drive units have their impedance and sound pressure level (SPL) measured. From these measurements, a set of model parameters are generated which describes the gross behaviour of each individual drive unit in terms of both magnitude and phase response.
   The natural response of the drive unit, as calculated from the model parameters, is then included in the crossover filter for that drive unit.
   The crossover filter (including the drive unit magnitude and phase response) is generated using a symmetrical finite impulse response (FIR) filter such that the filter exhibits zero phase distortion.
2. The measured impedance and SPL data for each individual loudspeaker drive unit is stored in the cloud.
   The measured data is accessible to configuration software which uploads the data for the specific drive units in a given loudspeaker and defines a bespoke crossover for the loudspeaker system in the home.
   Allows for automatic update to the crossover should a replacement drive unit be required for a loudspeaker. The data for generation of the model parameters for the replacement drive unit is drawn from the cloud.
   Should an improvement be made to the method of modelling the drive unit, this can also be automatically updated within the user's home.
   Should a new, improved, crossover be designed, this can be automatically updated within the user's home.

We will now look at these features in more depth.

Elimination of Phase Distortion from the Crossover and Drive Units in a Loudspeaker System.

The phase distortion arising from the crossovers and drive units of a conventional loudspeaker system is eliminated in the proposed system. To achieve this, the drive units are mounted in their respective enclosures and the drive unit input impedance is measured. From this measurement a model describing the mounted drive units' general electromechanical behaviour is derived. The drive unit model is then incorporated into the digital crossover filter for the loudspeaker system. The digital crossover is designed such that each combined filter produces a linear phase response. This ensures that both the crossover and drive unit phase distortion is eliminated and a known acoustic crossover is achieved.

The methods for deriving the drive unit model, incorporating the drive unit model into the crossover, and some detail of the digital crossover itself, are presented below.

### Drive Unit Modelling

The graph below shows a typical impedance curve of a drive unit mounted in an enclosure. In this case it is a 6″ driver in a sealed volume, but all moving coil drive units have a similar form.

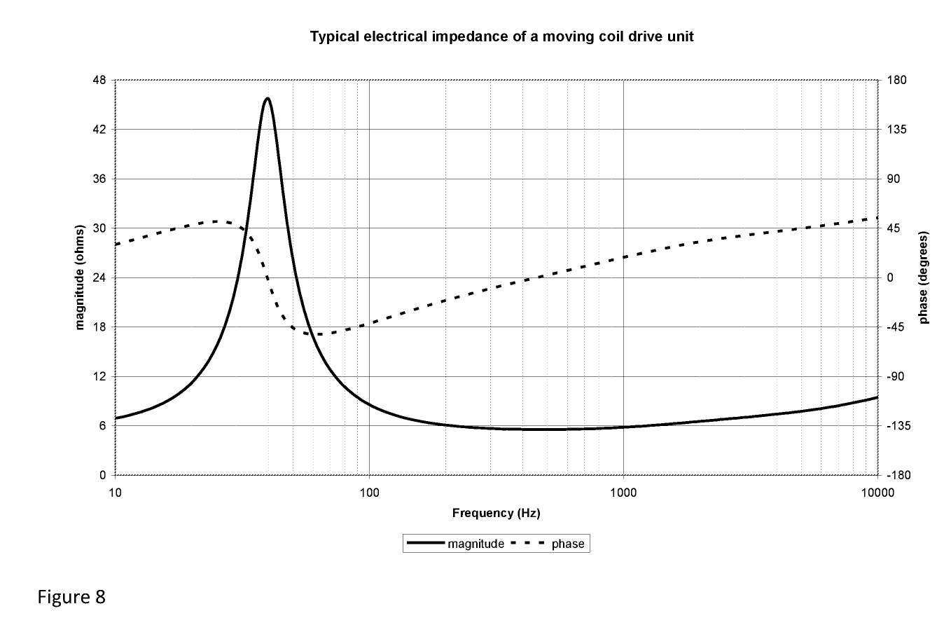

FIG. 8 shows an example of drive unit input impedance.

To establish the required drive unit parameters the following method is adopted. The principle resonance frequency, fₛ, is identified. The dc resistance of the speaker (R_{E}), and the impedance maxima at resonance, R_{E}+R_{ES}, is also identified.

To establish the total quality factor of the drive unit we find the frequencies either side of the resonance (f₁ and f₂) whose impedance is equal to R_{E}\sqrt{R_{C}}, where

$${R}_{C} = \frac{{R}_{E} + {R}_{ES}}{{R}_{E}} \qquad Eq . 2$$

Now by using R_{C}, fₛ, f₁ and f₂ we can derive the total quality factor, Q_{TS}, of the resonance.

$$\begin{matrix}{Q}_{MS} = \frac{{f}_{s} \sqrt{{R}_{C}}}{{f}_{2} - {f}_{1}} & Eq . 3 \\ {Q}_{ES} = \frac{{Q}_{MS}}{( {R}_{C} - 1 )} & Eq . 4 \\ {Q}_{TS} = \frac{{Q}_{ES} {Q}_{MS}}{{Q}_{ES} + {Q}_{MS}} & Eq . 5\end{matrix}$$

An estimation of the voice coil inductance, Lₑ, can be made using the formula below.

$${L}_{e} = \frac{( \frac{{R}_{E} \cdot 20 \cdot {10}^{3}}{2 π {f}_{3}} + 0.5 ) \cdot {10}^{- 3}}{20} \qquad Eq . 6$$

Where f₃ is the frequency above the minimum impedance point after resonance at which the impedance is 3 dB higher than the minimum point. It should be noted that equation 6 is an empirically derived equation; this is employed as the voice coil sitting in a motor system does not behave as a true inductor.

Alternatively, the voice coil inductance can be calculated for a spot frequency. This is often what is provided by drive unit manufacturers who typically specify the voice coil inductance at 1 kHz. In certain circumstances, for example if the required crossover points for the drive unit form a narrow band close to principle resonance, the voice coil inductance should be calculated at the desired crossover point. To do this, we first calculate

$${C}_{MES} = \frac{{Q}_{ES}}{2 π {f}_{s} {R}_{E}} \qquad Eq . 7$$

Then we calculate the reactive component of the measured impedance:

X=|Z|·sin θ Eq. 8

The inductive reactance is then calculated as:

$${X}_{L} = X + \frac{1}{2 π {fC}_{MES}} \qquad Eq . 9$$

Leading to a calculation for the voice coil inductance:

$${L}_{VC} = \frac{{X}_{L}}{2 π f} \qquad Eq . 10$$

Currently the four parameters; fₛ, Q_{TS}, R_{E} and Lₑ (or L_{VC} when required) provide the general model of the drive units phase response and magnitude variation. One final parameter is required to fully characterise the drive unit in the proposed system, namely its gross sound pressure level, or efficiency.

The simple four parameter electromechanical model detailed above adequately describes the a drive unit. Various models exist which provide a more comprehensive description of the semi-inductive behaviour of the voice coil in a loudspeaker drive unit. The system as described allows for the incorporation of improved electromechanical drive unit models as they become available. The improved model can then be pulled into the digital crossover.

Incorporating the Drive Unit Characteristics into the Crossover Filter

The drive unit characteristics are modelled by a simple band-pass filter with fₛ and Q_{TS} describing a 2^{nd} order high pass function, and R_{E} Lₑ a 1^{st} order low pass function. The high pass function can be described using Laplace notation as:

$${G}_{HP} ( s ) = \frac{{s}^{2}}{{s}^{2} + \frac{{ω}_{HP}}{Q} \cdot s + {ω}_{HP}^{2}} . \qquad Eq . 11$$

where,

ω_{HP}=2·π·fₛ Eq. 12.

and,

Q=Q_{TS} Eq. 13.

and the low pass function can be described as:

$${G}_{LP} ( s ) = \frac{1}{\frac{1}{{ω}_{LP}} \cdot s + 1} . \qquad Eq . 14$$

where,

$${ω}_{LP} = \frac{{R}_{E}}{{L}_{e}} . \qquad Eq . 15$$

The drive unit model is then described by:

G_{MODEL}=G_{HP}·G_{LP} Eq. 16.

The complex frequency response, F_{MODEL}, can now be calculated by evaluating the above expression using a suitable discrete frequency vector. The frequency vector should ideally have a large number of points to ensure maximum precision.

The frequency response of the desired crossover filter, F_{TARGET}, should also be evaluated over the same frequency vector. The required filter frequency response is then calculated as:

$${F}_{FILTER} = \frac{\vert {F}_{TARGET} \vert}{{F}_{MODEL}} . \qquad Eq . 17$$

Note that only the magnitude of the target frequency response is used as this ensures that the resulting response, F_{FILTER}·F_{DRIVEUNIT}, is linear phase.

### Filter Implementation

The requirement for overall linear phase means that infinite impulse response (IIR) filters are not suitable. Finite impulse response (FIR) filters are capable of arbitrary phase response so this type of filter is used. The filter coefficients are calculated as follows:

Firstly, the discrete-time impulse response of the complex frequency vector, F_{FILTER}, is calculated using the inverse discrete Fourier transform:

y_{FILTER}=DFT⁻¹[F_{FILTER}] Eq. 18.

y_{FILTER} will not be causal due to the zero-phase characteristic of |F_{TARGET}|, so a circular rotation is required to centre the response peak and create a realisable filter. The resulting impulse response can then be windowed in the usual manner to create a filter kernel of suitable length.

Physical implementation of the filter can take a number of forms including direct time-domain convolution and block-based frequency-domain convolution. Block convolution is particularly useful when the filter kernel is large, as is usually the case for low-frequency filters. A key aspect of the system is that all filter coefficients are stored within the loudspeaker and are capable of being reprogrammed without the need for specialised equipment.

Drive unit SPL is compensated by a simple digital gain adjustment. Relative time offsets due to drive-unit baffle alignment are compensated by digitally delaying the audio by the required number of sample periods.

### Storage of Drive Unit Model Parameters in the Cloud

The measured data is accessible to configuration software which uploads the data for the specific drive units in a given loudspeaker and defines a bespoke crossover for the loudspeaker system in the home.

This allows for automatic update to the crossover should a replacement drive unit be required for a loudspeaker. The data for generation of the model parameters for the replacement drive unit is drawn from the cloud. Should an improvement be made to the method of modelling the drive unit, this can also be automatically updated within the user's home. Should a new, improved, crossover be designed, this can be automatically updated within the user's home.

It is also possible, for the case of an integrated actively amplified loudspeaker system, to measure the impedance of the drive units from within an active amplifier module. This will allow the drive unit models to be continually updated to account for variations in operating temperature.

### Appendix 1—Timing Channel

This Appendix 1 describes an additional inventive concept.

### Method for Distributing a Digital Audio Signal

### Appendix 1: Background

### 1. Field

The concept relates to a method for distributing a digital audio signal; it solves a number of problems related to clock recovery and synchronisation.

### 2. Description of the Prior Art

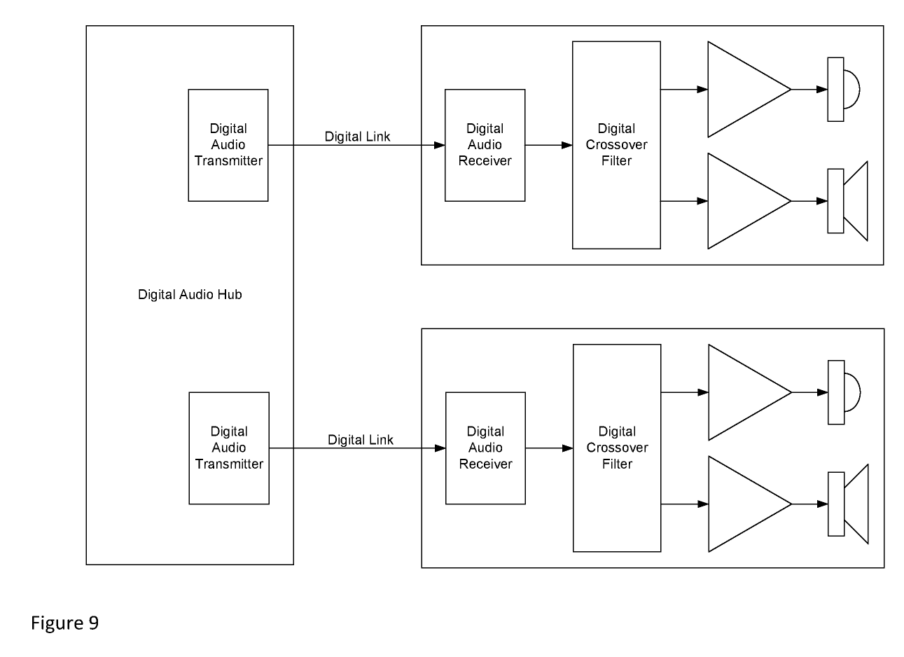

In a digital audio system, it is advantageous to keep the audio signal in the digital domain for as long as possible. In a loudspeaker, for example, it is possible to replace lossy analog cabling with a lossless digital data link (see FIG. 9). Operations such as crossover filtering and volume control can then be performed within the loudspeaker entirely in the digital domain. The conversion to analog can therefore be postponed until just before the signal reached the loudspeaker drive units.

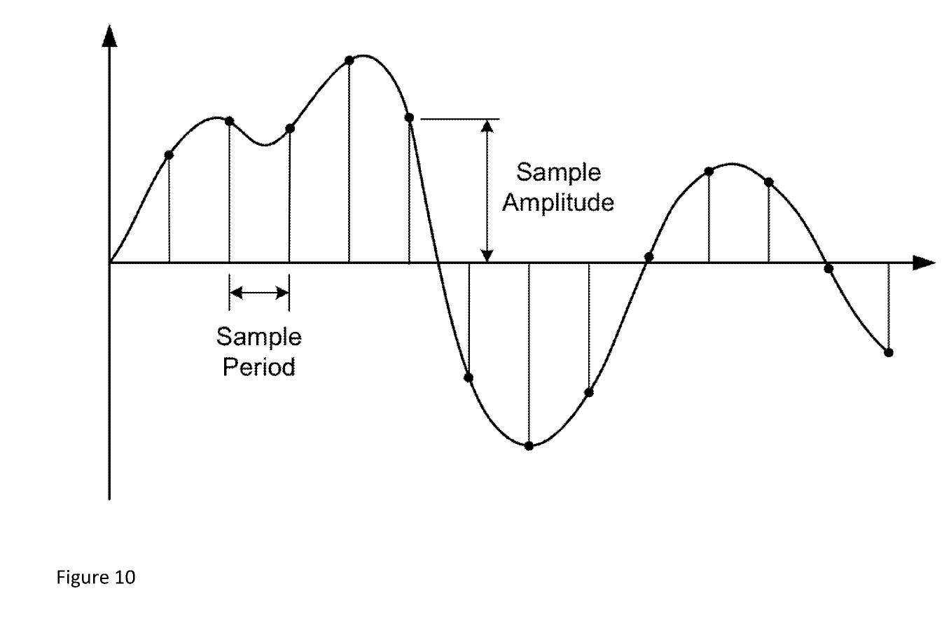

Any system for distributing digital audio must convey not only the sample amplitude values, but also the time intervals between the samples (FIG. 10). Typically, these time intervals are controlled by an electronic oscillator or ‘clock’, and errors in the period of this clock are often termed ‘clock jitter’. Clock jitter is an important parameter in analog-to-digital and digital-to-analog conversion as phase modulation of the sample clock can result in phase modulation of the converted signal.

Where multiple digital loudspeakers are employed, as in for example a stereo pair or a surround sound array, the multi-channel digital audio signal must be distributed over multiple connections. This presents a further problem as the timing relationship between each channel must be accurately maintained in order to form a stable three-dimensional audio image. The problem is further compounded by the need to transmit large amounts of data (up to 36.864 Mbps for 8 channels at 192 kHz/24-bit) as such high bandwidth connections are often, by necessity, asynchronous to the audio clock.

There are currently systems in existence that are capable of distributing digital audio to multiple devices, but they all have compromised performance, particularly with regard to clock jitter and synchronisation accuracy.

The Sony/Philips Digital Interface (SPDIF), also standardised as AES3 for professional applications, is a serial digital audio interface in which the audio sample clock is embedded within the data stream using bi-phase mark encoding. This modulation scheme makes it possible for receiving devices to recover an audio clock from the data stream using a simple phase-locked loop (PLL). A disadvantage of this system is that inter-symbol interference caused by the finite bandwidth of the transmission channel results in data-dependant jitter in the recovered clock. To alleviate this problem, some SPDIF clock recovery schemes use only the preamble patterns at the start of each data frame for timing reference. These patterns are free from data-dependant timing errors, but their low repetition rate means that the recovered clock jitter is still unacceptably high. Another SPDIF clock recovery scheme employs two PLL's separated by an elastic data buffer. The first PLL has a high bandwidth and relatively high jitter but is agile enough to accurately recover data bits and feed them into the elastic buffer. The occupancy of this buffer then controls a second, much lower bandwidth, PLL, the output of which both pulls data from the buffer and forms the recovered audio clock. High frequency jitter is greatly attenuated by this system, but low frequency errors remains due to the dead-band introduced by the buffer occupancy feedback mechanism. This low frequency drift is inaudible in a single receiver application, but causes significant synchronisation errors in multiple receiver systems.

The Multi-channel Audio Digital Interface (MADI, AES10) is a professional interface standard for distributing digital audio between multiple devices. The MADI standard defines a data channel for carrying multiple channels of audio data which is intended to be used in conjunction with a separately distributed synchronisation signal (e.g. AES3). The MADI data channel is asynchronous to the audio sample clock, but must have deterministic latency. The standard places a latency limit on the transport mechanism of +/−25% of one sample period which may be difficult to meet in some applications, especially when re-transmission daisy-chaining is required. Clock jitter performance is determined by the synchronisation signal, so is typically the same as for SPDIF/AES3.

Ethernet (IEEE802.3) is a fundamentally asynchronous interface standard and has no inherent notion of time, but enhancements are available that use Ethernet in conjunction with a number of extension protocols to provide some level of time synchronisation. AVB (Audio/Video Bridging), for example, uses the Precision Time Protocol (IEEE802.1AS) to synchronise multiple nodes to a single ‘wall clock’ and a system of presentation timestamps to achieve media stream synchronisation. In an audio application, sender audio samples are time-stamped by the sender using its wall-clock prior to transmission. Receivers then regenerate an audio clock from a combination of received timestamps and local wall-clock time. This system is less than optimal as there are numerous points at which timing accuracy can be lost: sender time-stamping, PTP synchronisation, and receiver clock regeneration. One useful feature of AVB is that it does allow for latency build-up due to multiple re-transmissions. This is achieved by advancing sender timestamps to take account of the maximum latency that is likely to be introduced.

In an ideal distribution system, the clock jitter of the receiver would be the same as that of the sender, and multiple receivers would have their clocks in perfect phase alignment. The distribution systems described above all fall short of this ideal as they fail to put sufficient emphasis on clock distribution. The main problem is the disparity between the frequency of the master audio oscillator and the frequency (or update rate) of the transmitted timing information.

Most modern audio converters (ADC's and DAC's) operate at a highly oversampled rate and typically require clock frequencies of between 128× and 512× the base sample rate. By contrast, the systems described above generate timing information at a much lower rate (1× the base sample rate, or less) so receivers must employ some form of frequency multiplication to generate the correct clock frequency. Frequency multiplication is not a lossless process and the resulting clock will have higher jitter than if the master clock had been transmitted and recovered at its native frequency.

The proposed system solves this problem by separating amplitude and timing data into two distinct channels, each optimised according to its own particular requirements.

### Summary of the Appendix 1 Concept

The concept is a method for distributing a digital audio signal in which timing information is transmitted in a continuous channel (‘the timing channel’) that is synchronous to an audio clock at a source and the timing channel includes information for both clock synchronization and sample synchronization; and in which audio sample data is transmitted in a separate channel (‘the data channel’) that is asynchronous to the timing channel.

Optional features in an implementation of the concept include any one or more of the following:
the data channel is optimized for data related parameters, such as bandwidth and robustness.
the timing channel is optimized for minimum clock jitter or errors in clock timing.
the timing channel is optimized for minimum clock jitter or errors in clock timing by including a clock signal with frequency substantially higher than the base sample rate, such as 128× the base sample rate.
a slave device receiving the timing channel is equipped with a low bandwidth filter to filter out any high frequency jitter introduced by the channel so that the jitter of a recovered slave clock is of the same order as the jitter in a master clock oscillator.
sample synchronization for the data channels used in a multi-channel digital audio signal, such as stereo or surround sound, is preserved by a master device including a sample counter and each slave device also including a sample counter, and the master device then inserts into the timing channel a special sync pattern at predefined intervals, such as every 2¹⁶ samples, which when detected at a slave device causes that slave device to reset its sample counter.
each master device includes (i) a master audio clock, which is the clock for the entire system, including all slaves, (ii) a timing channel generator, (iii) a sample counter and (iv) a data channel generator.
each slave device includes (i) a timing channel receiver, (ii) a jitter attenuator, (iii) a sample counter and (iv) data channel receive buffer.
each slave device achieves clock synchronisation with the master by recovering a local audio clock directly from the timing channel using a phase-locked loop.
each slave device achieves sample synchronization by detecting the synchronization pattern embedded within the timing channel.
each audio sample frame, sent over the data channel, includes sample data plus an incrementing index value and the index value is read and compared at a sample counter in each slave, that sample counter incrementing with each clock signal received on the timing channel, so that if the index value (‘Data Index’) for a sample matches or corresponds to the local sample count (‘Timing Index’), then that sample is considered to be valid and is passed on to the next process in the audio chain.
a data channel receive buffer at a slave device operates such that if the Data Index is ahead of the Timing Index, then the buffer is stalled until the Timing Index catches up; and if the Data Index is lags behind the Timing Index, then the buffer is incremented until the Data Index catches up.
an offset is added to a sample index sent by the master to enable a data channel receive buffer at each slave to absorb variations in transmission timing of up to several sample periods.
phase error introduced by the synchronisation information has a high frequency signature that is filtered out by a filter, such as a PLL, at each slave device.
a master device generates the timing channel and also the sample data and sample indexes.
a master device generates the timing channel but slave devices generate the sample data and sample indexes.
a bidirectional full duplex data channel is used where the master device both sends and also receives sample data and sample indexes.
various different connection topologies are enabled, such as point-to-point, star, daisy-chain and any combination of these.
any transmission media is supported for either data or timing channels, and different media can be used for data and timing channels.

Other aspects include the following:

A first aspect is a system comprising a digital audio source distributing a digital audio signal to a slave, such as a loudspeaker, in which timing information is transmitted in a continuous channel (‘the timing channel’) that is synchronous to an audio clock at a source and the timing channel includes information for both clock synchronization and sample synchronization; and in which audio sample data is transmitted in a separate channel (‘the data channel’) that is asynchronous to the timing channel. The system may distribute a digital audio signal using any one or more of the features defined above.

A second aspect is a media output device, such as a smartphone, tablet, home computer, games console, home entertainment system, automotive entertainment system, or headphones, receiving a digital audio signal from a digital audio source, in which the media output device is adapted or programmed to receive and process:

(i) timing information that is transmitted in a continuous channel (‘the timing channel’) that is synchronous to an audio clock at a source, the timing channel including information for both clock synchronization and sample synchronization; and also
(ii) audio sample data that is transmitted in a separate channel (‘the data channel’) that is asynchronous to the timing channel.

The media output device may be adapted to receive and process a digital audio signal that has been distributed using any one or more of the features defined above.

A third aspect is a software-implemented tool that enables a digital audio system to be designed, the system comprising a digital audio source distributing a digital audio signal to a slave, such as a loudspeaker, in which timing information is transmitted in a continuous channel (‘the timing channel’) that is synchronous to an audio clock at a source and the timing channel includes information for both clock synchronization and sample synchronization; and in which audio sample data is transmitted in a separate channel (‘the data channel’) that is asynchronous to the timing channel.

The software-implemented tool may enable the digital audio system to distribute a digital audio signal using any one or more of the features defined above.

A fourth aspect is a media streaming platform or system which streams media, such as music and/or video, to networked media output devices, such as smartphones, tablets, home computers, games consoles, home entertainment systems, automotive entertainment systems, and headphones, in which the platform is adapted or programmed to handle or interface with:

(i) timing information that is transmitted in a continuous channel (‘the timing channel’) that is synchronous to an audio clock at a source, the timing channel including information for both clock synchronization and sample synchronization; and also:
(ii) audio sample data that is transmitted in a separate channel (‘the data channel’) that is asynchronous to the timing channel.

The media streaming platform or system may be adapted to handle or interface with a digital audio signal distributed using any one or more of the features defined above.

### Appendix 1 Detailed Description

A new digital audio connection method is proposed which solves a number of problems related to clock recovery and synchronisation. Data and timing information are each given dedicated transmission channels. The data channel is free from any synchronisation constraints and can be chosen purely on the basis of data related parameters such as bandwidth and robustness. The timing channel can then be optimised separately for minimum jitter. A novel synchronisation scheme is employed to ensure that even when the data channel is asynchronous, sample synchronisation is preserved. The new synchronisation system is particularly useful for transmitting audio to multiple receivers.

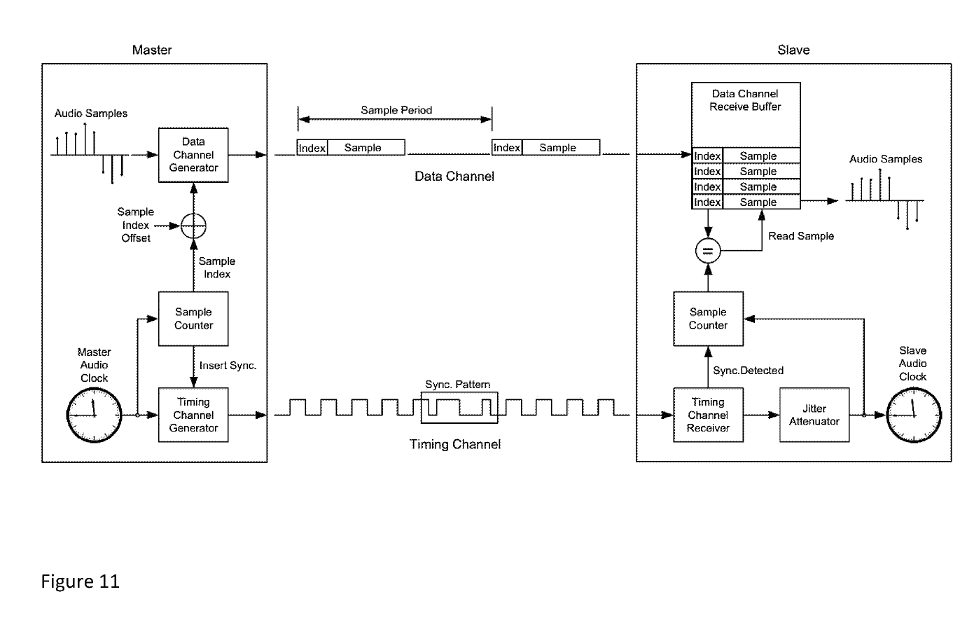

With reference to FIG. 11, the proposed system consists of two discreet channels: a data channel and a timing channel.

Audio samples generated by the link master are sent out over the data channel every sample period. Each audio sample frame consists of the raw sample data for all channels plus an incrementing index value. A checksum is also added to enable each slave to verify the data it receives. There is no requirement for the data channel to be synchronous to the audio clock so a wide range of existing data link standards may be used. Spare capacity in the data channel can be used to send control and configuration data as long as the total frame length does not exceed the sample period.

The link master also generates the audio clock for the entire system. This clock is broadcast to all link slaves over the timing channel. In order to avoid unnecessary frequency division in the master and potentially lossy frequency multiplication in the slave, the frequency of the transmitted clock is maintained at a high rate, typically 128× the base sample rate. Any physical channel can be used as long as the transmission characteristics are conducive to low jitter and overall latency is low and deterministic. All transmission channels introduce some jitter so each slave device is equipped with a low bandwidth PLL to ensure that any high frequency jitter introduced by the channel is filtered out. A key aspect of this system is that the jitter of the recovered slave clocks should be of the same order as the jitter in the master clock oscillator.

Synchronisation between data and timing channels is achieved using sample counters. Both master and slave devices have a counter which increments with each sample tick of their respective audio clocks. A special sync pattern is inserted into the timing channel each time the master sample counter rolls over (typically every 2¹⁶ z samples). This sync pattern is detected by slave devices and causes their sample counters to be reset. This ensures that all slave sample counters are perfectly synchronised to the master.

Audio samples received over the data channel are fed into a short FIFO (first-in, first-out) buffer, along with their corresponding index values. At the other end of this buffer, samples are read and their index values compared with the local sample count. When these values match, the sample is considered valid and is passed on to the next process in the audio chain.

Due to the asynchronous nature of the data channel, transmission times between master and slave can vary slightly. The proposed system copes with this by adding an offset to the sample index sent by the master. This essentially fools the slaves into thinking the samples have been sent early and allows the receive FIFO to absorb variations in transmission timing of up to several sample periods. This feature is especially useful in daisy-chain applications where the data channel may undergo several demodulation/modulation cycles. The master can also adjust the sample index offset to suit particular data channels and connection topologies. This feature is useful in audio/video applications where audio latency must be kept to a minimum.

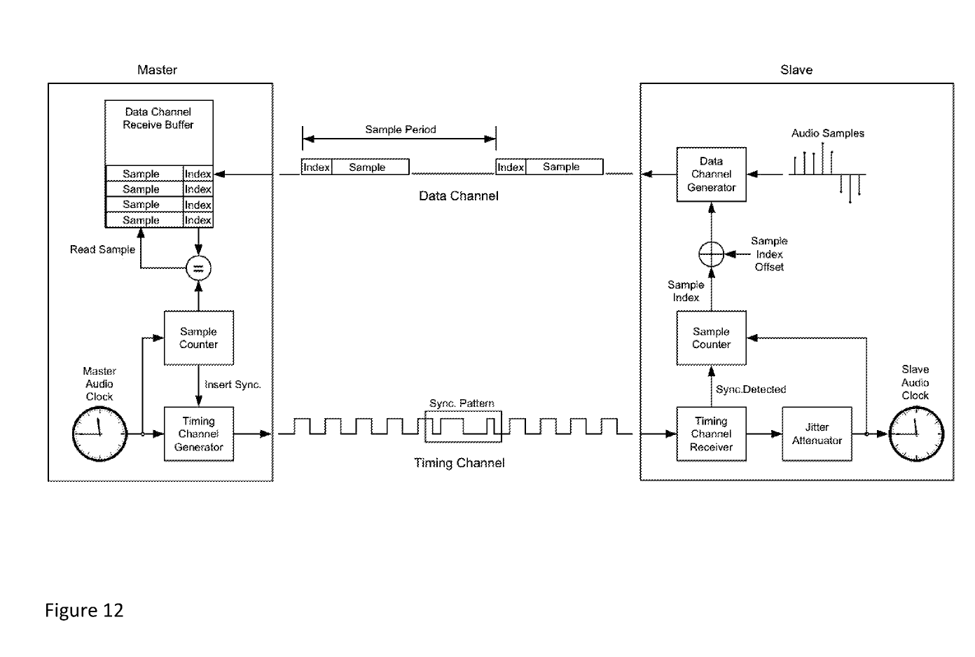

Although the above description relates to the transmission of audio from a central master device to multiple slaves, it should be obvious that by reversing the flow of data, the central master device could also receive audio from each slave. In the reversed case, the master device is still responsible for generating the timing channel and slaves are responsible for generating the sample data and corresponding sample indexes (see FIG. 12). Clearly, both systems could be combined to create a bidirectional link using a suitable full-duplex data channel.

Similarly, control and configuration data can also be bidirectional (assuming the data channel is bidirectional). This is particularly useful for implementing processes such as device discovery, data retrieval, and general flow control.

A further enhancement for error prone data channels is forward error correction. This involves the generation of special error correction syndromes at the point of transmission that allow the receiver to detect and correct data errors. Depending on the characteristics of the channel, more complex schemes involving data interleaving may also be employed to improve robustness under more prolonged error conditions.

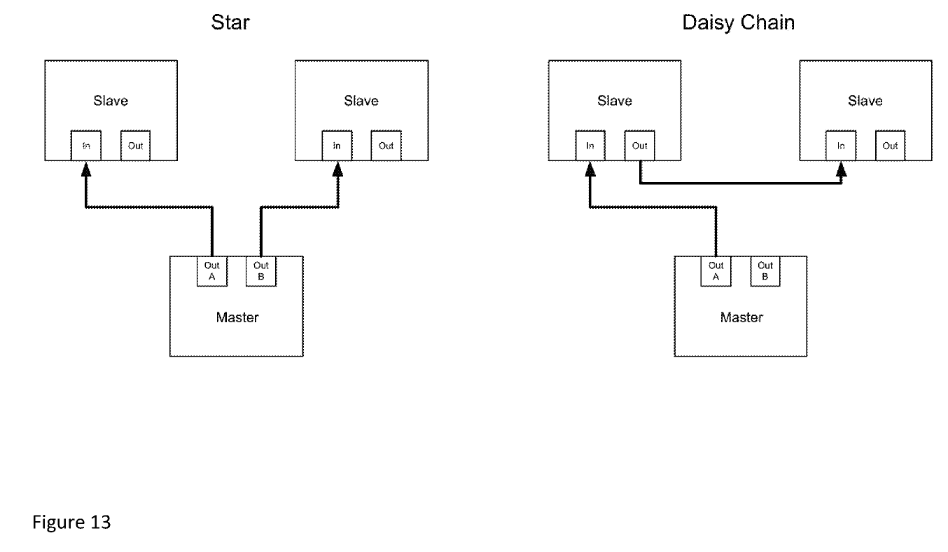

An important aspect of the proposed system is that allows for a number of different connection topologies. In a wired configuration, each connection is made point-to-point as this allows transmission line characteristics to be tightly controlled. However, it is still possible to connect multiple devices in a variety of different configurations using multiple ports (see FIG. 13). Master devices for example can have multiple transmit ports to enable star configurations. Slave devices can also be equipped with transmit ports to enable daisy-chain configurations. Clearly, more complex topologies are also possible by combining star and daisy-chain connections.

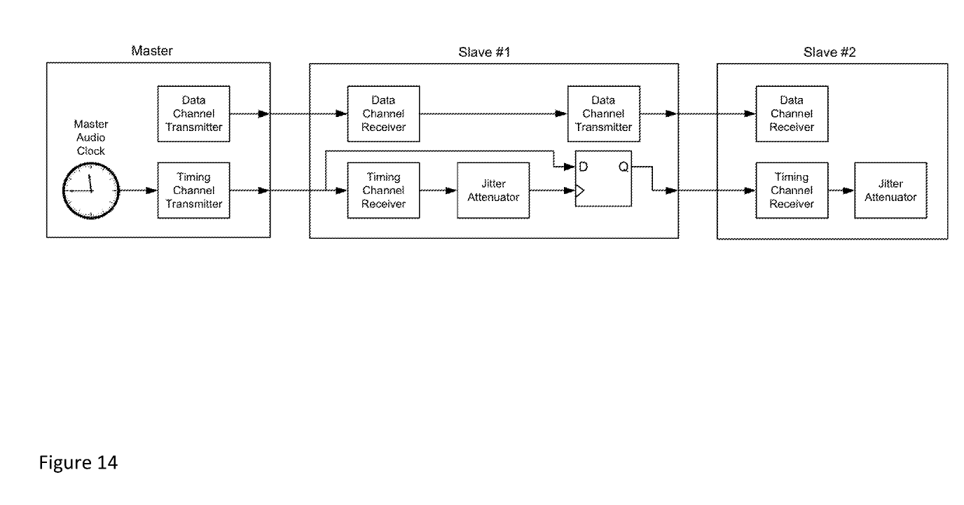

One potential problem with the daisy-chain configuration is that the reception and re-transmission of the timing channel could result in an accumulation of jitter. This problem can be avoided by re-clocking the timing channel prior to retransmission using the clean recovered clock (see FIG. 14). The re-clocking action will delay the timing channel by approximately half a recovered clock period, but this is usually small enough to be insignificant.

Although the above description refers largely to wired applications, the basic synchronisation principals can be applied to almost any form of transmission media. It is even possible to have the data channel and timing channel transmitted over different media. As an example, it would be possible to send the data channel over an optical link and use a radio-frequency beacon to transmit the timing channel. It would also be possible to use a wireless link for data and timing where the timing channel is implemented using the wireless carrier.

### Specific Embodiment

An example of a specific embodiment will now be described that uses the 100Base-TX (IEEE802.3) physical layer standard to implement a data channel that is unidirectional for audio data, and bidirectional for control data. Audio bandwidth is sufficient to carry up to 8 channels of 192 kHz/24-bit audio. The timing channel is implemented using LVDS signalling over a spare pair of wires in the 100Base-TX cable.

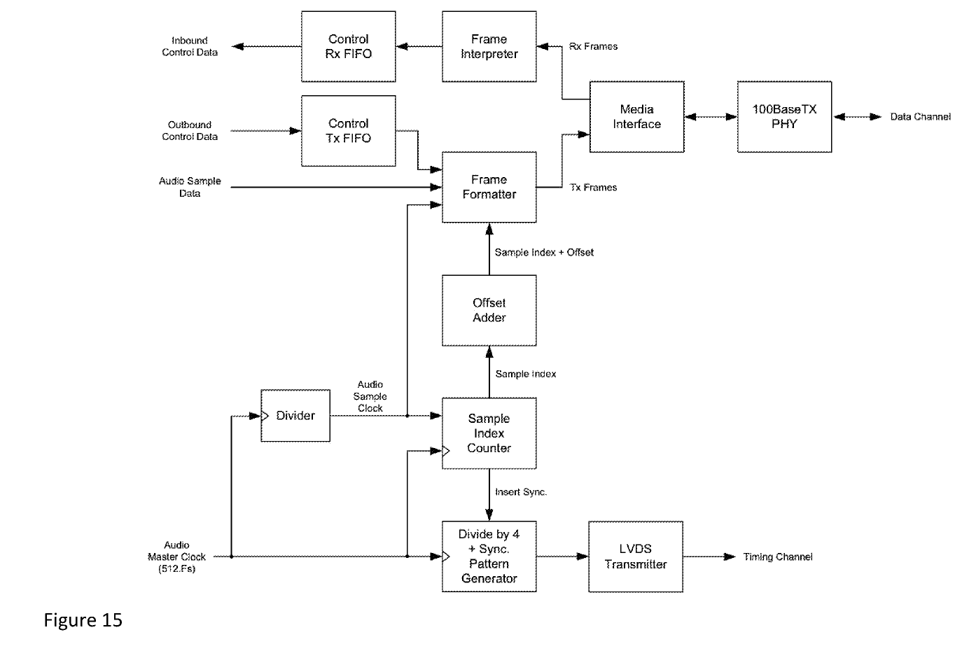

A block diagram of the Master interface is shown in FIG. 15.

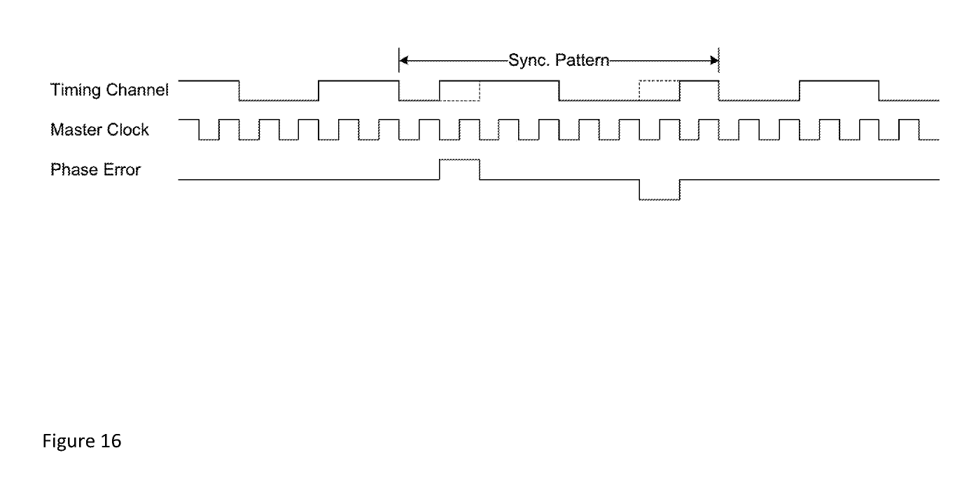

An audio master clock running at either 512×44.1 kHz or 512×48 kHz, depending on the current sample rate family, is divided down to generate an audio sample clock. This sample clock is then used to increment a sample index counter. An offset is added to the sample index to account for the worst case latency in the data channel. The timing channel is generated by a state-machine that divides the audio master clock by four and inserts a sync pattern when the sample index counter rolls over. The sync pattern (see FIG. 16) is a symmetrical deviation from the normal timing channel toggle sequence. The phase error introduced by the sync pattern has a benign high-frequency signature that can be easily filtered out by the slave PLL.

The timing interfaces to one of the spare data pairs in the 100Base-TX cable via an LVDS driver and an isolation transformer.

The data channel is bidirectional with Tx frames containing audio and control data, and Rx frames containing only control data. A standard 100Base-TX Ethernet physical layer transceiver is used to interface to the standard Tx and Rx pairs within the 100Base-TX cable.

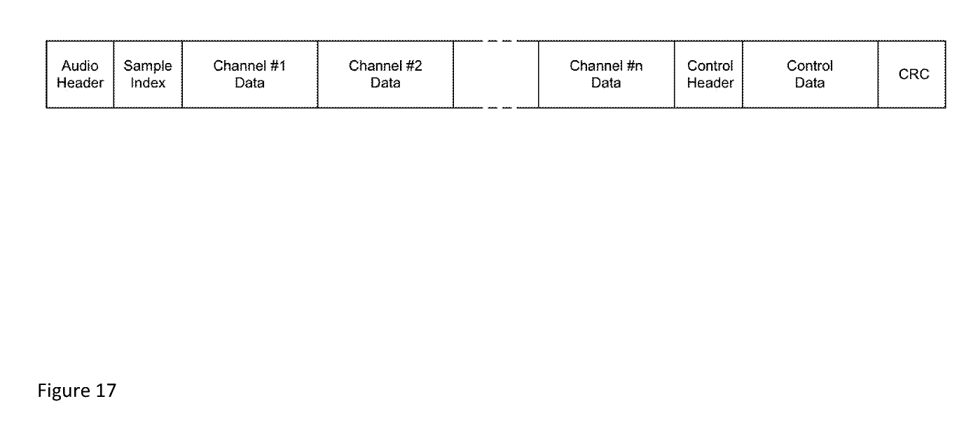

Tx frames are generated every audio sample period. A frame formatter combines the offset sample index, sample data for all channels, and control data into a single frame (see FIG. 17). A CRC word is calculated as the frame is constructed and appended to the end of the frame. Control data is fed through a FIFO buffer as this enables the frame formatter to regulate the amount of control data inserted into each frame. Frame length is controlled such that frames can be generated every sample period whilst still meeting the frames inter-frame gap requirements of the 100Base-TX standard.

Rx frames are received and decoded by a frame interpreter. The frame CRC is checked and valid control data is fed into a FIFO buffer.

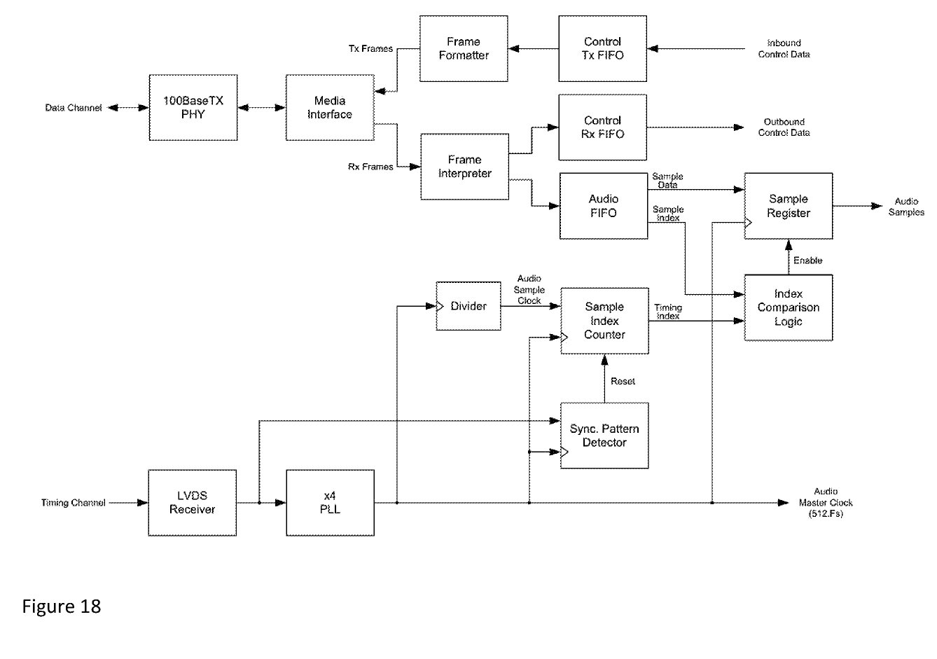

A block diagram of the Slave interface is shown in FIG. 18.

The timing channel receiver interface consists of an isolating transformer and an LVDS receiver. The resulting signal is fed into a low-bandwidth PLL which simultaneously filters out high-frequency jitter (including the embedded sync pattern) and multiples the clock frequency by a factor of four. The output of this PLL is then used as the master audio clock for subsequent digital-to-analog conversion. The recovered clock is also divided down to generate the audio sample clock which in turn is used to increment a sample index counter.

Sync patterns are detected by sampling the raw timing channel signal using the PLL recovered master clock. A state-machine is used to detect the synchronisation bit pattern described in FIG. 16. Absolute bit polarity is ignored to ensure that the detection process works even when the timing channel signal is inverted. The detection of a sync pattern causes the slave sample index counter to be reset such that it becomes synchronised to the master sample index counter.

As with the master interface, a standard 100Base-TX Ethernet physical layer transceiver is used to interface to the Tx and Rx pairs within the 100Base-TX cable. Rx frames are received and decoded by a frame interpreter. The frame CRC is checked and valid audio and control data is fed into separate FIFO buffers. Only the audio channels of interest are extracted. The audio FIFO entries consist of a concatenation of the audio sample data and the sample index from the received frame. At the other end of this FIFO buffer, a state-machine compares the sample index from each FIFO entry with the locally generated sample index value.

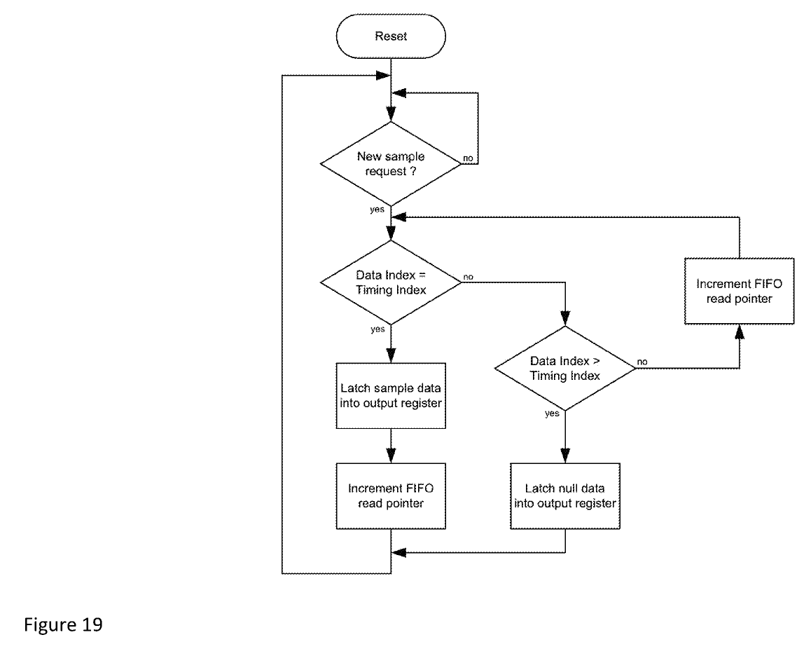

A flow-chart showing a simplified version of the index comparison logic is shown in FIG. 19. For clarity, the locally generated sample index is referred to as the Timing Index, and the FIFO entry sample index is referred to as the Data Index. Each time a new audio sample is requested by the audio sample clock, the Data Index is compared with the Timing Index. If the index values match, the audio sample data is latched into an output register. If the Data Index is ahead of the Timing Index, null data is latched into the output register and the FIFO is stalled until the Timing Index catches up. If the Data Index lags behind the Timing Index, the FIFO read pointer is incremented until the Data Index catches up. The audio FIFO should have sufficient entries to deal with the maximum sample index offset which is typically 16 samples. Slave Tx frames contain only control data but flow control is still required to meet the inter-frame gap requirements of the 100Base-TX standard, and to avoid overloading the master's Control Rx FIFO. Tx frames are generated by a frame formatter which pulls data from the Control Tx FIFO and calculates and appends a CRC word.

Clock jitter measured at the PLL output of a slave connected via 100m of Cat-5e cable is less than 10 ps, which is comparable with the jitter measured at the master clock oscillator and significantly less than the 80 ps measured from the best SPDIF/AES3 receiver.

Synchronisation between multiple slaves is limited only by the matching of cable lengths and the phase offset accuracy of the PLL. Typically, the absolute synchronisation error is less than 1 ns. The differential jitter measured between the outputs of two synchronised slaves is less than 25 ps. These figures are orders of magnitude better than that achievable with AVB.

Latency is determined by the sample index offset which is set dynamically according to sample rate. At a sample rate of 192 kHz, an offset of 16 samples is used which corresponds to a latency of 83.3 us. This value is well within acceptable limits for audio/video synchronisation and real-time monitoring.

### Summary of Some Key Features in an Appendix 1 Implementation

A system for distributing digital audio using separate channels for data and timing information whereby timing accuracy is preserved by a system of sample indexing and synchronisation patterns, and clock jitter is minimised by removing unnecessary frequency division and multiplication operations.

Optional features include any combination of the following:
control information is transferred using spare capacity in the data channel.
the flow of audio data is opposite to the flow of timing information.
audio data flows in both directions.
forward error correction methods are used to minimise data loss over error-prone channels.
audio data is encrypted to prevent unauthorised playback.
the physical transmission method is wired
the physical transmission method is wireless
the physical transmission method is optical.
the physical transmission method is a combination of the above.

### Appendix 1: Numbered and Claimed Concepts

1. Method for distributing a digital audio signal in which timing information is transmitted in a continuous channel (‘the timing channel’) that is synchronous to an audio clock at a source and the timing channel includes information for both clock synchronization and sample synchronization; and in which audio sample data is transmitted in a separate channel (‘the data channel’) that is asynchronous to the timing channel.

2. The method of claim 1 in which the data channel is optimized for data related parameters, such as bandwidth and robustness.

3. The method of any preceding Claim in which the timing channel is optimized for minimum clock jitter or errors in clock timing.

4. The method of any preceding Claim in which the timing channel is optimized for minimum clock jitter or errors in clock timing by including a clock signal with frequency substantially higher than the base sample rate, such as 128× the base sample rate.

5. The method of any preceding Claim in which a slave device receiving the timing channel is equipped with a low bandwidth filter to filter out any high frequency jitter introduced by the channel so that the jitter of a recovered slave clock is of the same order as the jitter in a master clock oscillator.

6. The method of any preceding Claim in which sample synchronization for the data channels used in a multi-channel digital audio signal, such as stereo or surround sound, is preserved by a master device including a sample counter and each slave device also including a sample counter, and the master device then inserts into the timing channel a special sync pattern at predefined intervals, such as every 2¹⁶ samples, which when detected at a slave device causes that slave device to reset its sample counter.

7. The method of claim 6 in which each master device includes (i) a master audio clock, which is the clock for the entire system, including all slaves, (ii) a timing channel generator, (iii) a sample counter and (iv) a data channel generator.

8. The method of claim 6 or 7 in which each slave device includes (i) a timing channel receiver, (ii) a jitter attenuator, (iii) a sample counter and (iv) data channel receive buffer.

9. The method of claim 8 in which each slave device achieves clock synchronisation with the master by recovering a local audio clock directly from the timing channel using a phase-locked loop.

10. The method of claim 8 or 9 in which each slave device achieves sample synchronization by detecting the synchronization pattern embedded within the timing channel.

11. The method of any preceding Claim in which each audio sample frame, sent over the data channel, includes sample data plus an incrementing index value and the index value is read and compared at a sample counter in each slave, that sample counter incrementing with each clock signal received on the timing channel, so that if the index value (‘Data Index’) for a sample matches or corresponds to the local sample count (‘Timing Index’), then that sample is considered to be valid and is passed on to the next process in the audio chain.

12. The method of claim 11 in which a data channel receive buffer at a slave device operates such that if the Data Index is ahead of the Timing Index, then the buffer is stalled until the Timing Index catches up; and if the Data Index is lags behind the Timing Index, then the buffer is incremented until the Data Index catches up.

13. The method of any preceding claim 11 or 12 in which an offset is added to a sample index sent by the master to enable a data channel receive buffer at each slave to absorb variations in transmission timing of up to several sample periods.

14. The method of any preceding Claim in which phase error introduced by the synchronisation information has a high frequency signature that is filtered out by a filter, such as a PLL, at each slave device.

15. The method of any preceding Claim in which a master device generates the timing channel and also the sample data and sample indexes.

16. The method of any preceding Claim in which a master device generates the timing channel but slave devices generate the sample data and sample indexes.

17. The method of any preceding Claim in which a bidirectional full duplex data channel is used where the master device both sends and also receives sample data and sample indexes.

18. The method of any preceding Claim in which various different connection topologies are enabled, such as point-to-point, star, daisy-chain and any combination of these.

19. The method of any preceding Claim in which any transmission media is supported for either data or timing channels, and different media can be used for data and timing channels.

21. A system comprising a digital audio source distributing a digital audio signal to a slave, such as a loudspeaker, in which timing information is transmitted in a continuous channel (‘the timing channel’) that is synchronous to an audio clock at a source and the timing channel includes information for both clock synchronization and sample synchronization; and in which audio sample data is transmitted in a separate channel that is asynchronous to the timing channel.

22. The system of claim 21 distributing a digital audio signal using the method of any claim 1-19.

23. A media output device, such as a smartphone, tablet, home computer, games console, home entertainment system, automotive entertainment system, or headphones, receiving a digital audio signal from a digital audio source, in which the media output device is adapted or programmed to receive and process:

(i) timing information that is transmitted in a continuous channel (‘the timing channel’) that is synchronous to an audio clock at a source, the timing channel including information for both clock synchronization and sample synchronization; and also
(ii) audio sample data that is transmitted in a separate channel that is asynchronous to the timing channel.

24. The media output device of claim 23, adapted to receive and process a digital audio signal that has been distributed using the method of any claim 1-19.

24. A software-implemented tool that enables a digital audio system to be designed, the system comprising a digital audio source distributing a digital audio signal to a slave, such as a loudspeaker, in which timing information is transmitted in a continuous channel (‘the timing channel’) that is synchronous to an audio clock at a source and the timing channel includes information for both clock synchronization and sample synchronization; and in which audio sample data is transmitted in a separate channel that is asynchronous to the timing channel.

25. The software-implemented tool of claim 24, which enables the digital audio system to distribute a digital audio signal using the method of any claim 1-19.

26. A media streaming platform or system which streams media, such as music and/or video, to networked media output devices, such as smartphones, tablets, home computers, games consoles, home entertainment systems, automotive entertainment systems, and headphones, in which the platform is adapted or programmed to handle or interface with:

(i) timing information that is transmitted in a continuous channel (‘the timing channel’) that is synchronous to an audio clock at a source, the timing channel including information for both clock synchronization and sample synchronization; and also:
(ii) audio sample data that is transmitted in a separate channel that is asynchronous to the timing channel.

27. The media streaming platform or system of claim 26, adapted to handle or interface with a digital audio signal distributed using the method of any claim 1-19.

### Appendix 1 Abstract

Method for distributing a digital audio signal in which timing information is transmitted in a continuous channel (‘the timing channel’) that is synchronous to an audio clock at a source and the timing channel includes information for both clock synchronization and sample synchronization; and in which audio sample data is transmitted in a separate channel that is asynchronous to the timing channel. The data channel is optimized for data related parameters, such as bandwidth and robustness. The timing channel is optimized for minimum clock jitter or errors in clock timing.

### Appendix 2—Room Mode Optimisation

This Appendix 2 describes an additional inventive concept.

### Method for Optimizing the Performance of a Loudspeaker to Compensate for Low Frequency Room Modes

### APPENDIX 2: Background

### 1. Field

The concept relates to method for optimizing the performance of a loudspeaker in a given room or other environment to compensate for sonic artefacts resulting from low frequency room modes.

### 2. Description of the Prior Art

### Room Mode Optimisation

Consider a sound-wave travelling directly towards a room surface and being reflected, the incident and reflected waves will be coincident (but travelling in opposite directions). In a rectangular room, the reflected wave will be reflected again from the opposite surface. If the wavelength happens to be simply related to the room dimension, then the reflections will be phase synchronous. Two such waves travelling in opposite directions will establish a standing wave pattern, or mode, in which the local sound pressure variations are consistently higher in some places than in others. This situation occurs at frequencies for which the room dimension, in each of the three dimensions, is an integer multiple of one-half wavelength of the sound-wave. Furthermore, this triple subset (in x, y and z dimensions of the room) of ‘axial’ modes is only one of three types of mode. Reflections involving four surfaces in turn are described as ‘tangential’; those involving reflections from all six surfaces are described as ‘oblique’.

The upshot of room modes is that in some positions within a room low frequency sounds will be accentuated while in others they will be reduced. Perhaps of more importance are the relative decay times of the modal frequencies. Room modes, due to their resonant nature, remain present in the room for longer than sounds at frequencies that do not lie on a room mode. This extra decay time is very audible and causes masking of other frequencies during the decay time of the mode. This is why a bad room sounds ‘boomy’, making it more difficult to follow the tune.

Room mode correction is by no means new; it has been treated by many others over the years. In most instances the upper frequency limit for mode correction has been defined by Schroeder frequency which approximately defines the boundary between reverberant room behaviour (high frequency) and discrete room modes (low frequency). In listening tests we found this to be too high in frequency for most rooms. In a typical sized room the Schroeder frequency falls between 150 Hz and 250 Hz, well into the vocal range and also the frequency range covered by many musical instruments. Applying sharp corrective notches in this frequency range not only reduces amplitude levels at the modal frequencies but also introduces phase distortion. The direct sound from the loudspeaker to the listener is therefore impaired in both magnitude and phase in a very critical frequency range for music perception. Due to the precedence effect, also known as the Hass effect, any room related response occurs subsequent to the first arrival (from loudspeaker direct to the listener) the sound energy from room reflections simply supports the first arrival. If the first arrival is contains magnitude and phase distortion through the vocal and fundamental musical frequency range the errors are clearly audible and are found to reduce the musical qualities of the audio reproduction system.

Problems with Microphone Based Optimisation Techniques

Most microphone based room correction techniques rely on a number of assumptions regarding a desired ‘target’ response at the listening position. Most commonly this target is a flat frequency response, irrespective of the original designed frequency response of the loudspeaker system being corrected.

Often microphone based correction algorithms will apply both cut and boost to signals to correct the in-room response of a loudspeaker system to the desired target response. The application of boosted frequencies can cause the loudspeakers to be overdriven resulting in physical damage to the loudspeaker drive units either by excess mechanical movement or damage to the electrical parts through clipped amplifier signals. Typically an active loudspeaker, whose amplification is built into the loudspeaker to comprise a complete playback system, is designed to ensure that the dynamic range of the loudspeaker drive units match the dynamic range of the amplifiers. If a room correction regime applies boost to an active loudspeaker system there is an increased risk of overdriving and damaging the system.

Microphone correction systems often result in a sweet spot where the sound is adequately corrected to the desired target response. Outside of this (often very) small area the resulting sound may be left less ideal than it was prior to correction.

Where microphone measurements are provided to an end user for further human correction too often little can be deduced regarding room effects from the measured response. Aberrations in the measured pressure response may be caused by a number of factors including; room acoustic effects, constructive and destructive interference from the multiple loudspeakers and their individual drive units, inappropriate or un-calibrated hardware (both source and receiver), physical characteristics of the loudspeaker (baffle step or diffraction effects). When a lay user appraises the measured response there is little to inform him of whether observed aberrations are due to room interaction, characteristics of the loudspeaker system, or artefacts of the measurement. As a result corrective filtering is often applied in error, resulting in poor system response and the potential of damage.

### Summary of the Appendix 2 Concept

The invention is a method for optimizing the performance of a loudspeaker in a given room or other bounded space to compensate for sonic artefacts comprising the step of (a) automatically modelling the acoustics of the bounded space and then (b) automatically affecting or modifying the signal in order to mitigate aberrations associated with room resonances, using a corrective optimisation filter automatically generated with that modelling.

Optional features in an implementation of the concept include any one or more of the following:
a method in which low frequency peaks resulting from room resonances are mitigated by modifying the signal sent to a loudspeaker.
a corrective optimization filter that automatically affects, modifies or decreases the low frequency peaks is generated using a loudspeaker-to-listener transfer function in the presence of room modes.
the transfer function is derived from the coupling between low frequency sources and the listener and the modal structure of the room.
a modal summation approach is used, whereby the coupling between low frequency sources and the listener and the modal structure of the room are assessed.
room modes above the frequency at which the precedence effect, as defined by Haas, and that allow human determination of the direct sound separately from the room response, are deliberately not treated.
room modes above approximately 80 Hz are deliberately not treated.
the corrective optimization filter is derived by modelling the low frequency sources in a loudspeaker and their location(s) within the bounded acoustic space.
the bounded acoustic space is assumed to have a generalized acoustic characteristic and/or the acoustic behaviour of the boundaries are further defined by their absorption/transmission characteristics.
the corrective optimization filter substantially treats only those modal peaks that are in the vicinity of a listening position.
modelling each low frequency sources uses the frequency response prescribed by a digital crossover filter for that source.
the basic shape of the room is assumed to be rectangular and a user can alter the corrective optimization filter to take into account different room shapes.
the corrective optimization filter is calculated locally, such as in the music system that includes the loudspeaker.
the corrective optimization filter is calculated remotely at a server, such as in the cloud, using room data that is sent to the server.
the remote server stores the frequency response prescribed by the digital crossover filter for each source and uses that response data when calculating a filter.
the filter and associated room model/dimensions for one room are re-used in creating filters for different rooms.
the filter can be dynamically modified and re-applied by an end-user.
user-modified filter settings and associated room dimensions are collated and processed to provide feedback to both the user and the predictive model.
user adjustments, such as user-modified filter settings that differ from model predicted values are collated according to room dimensions and this information is then used to (i) suggest settings for non-rectangular rooms, and/or (ii) provide alternative settings for rectangular rooms that may improve sound quality, and/or (iii) provide feedback to the model such that it can learn and provide better compensation over a wider range of room shapes.
the method enables the quality of music reproduction to be optimized, taking into account the acoustic properties of furnishings in the room or other environment.
the method enables the quality of music reproduction to be optimized, taking into account the required position of the speakers in the room or other environment.
the method does not require any microphones and so the acoustics are modelled and not measured.

Other aspects include the following:

A first aspect is a loudspeaker optimized for a given room or other bounded space, the loudspeaker automatically affecting, modifying or decreasing low frequency peaks associated with interacting sound waves in that bounded space by virtue of being automatically configured using a model of the acoustics of the bounded space.

The loudspeaker may be optimised for performance using the features in any method defined above.

A second aspect is a media output device, such as a smartphone, tablet, home computer, games console, home entertainment system, automotive entertainment system, or headphones, comprising at least one loudspeaker optimized for a given room or other bounded space, the loudspeaker automatically affecting, modifying or decreasing low frequency peaks associated with interacting sound waves in that bounded space by virtue of being automatically configured using a model of the acoustics of the bounded space.

The loudspeaker in the media output device may be optimised for performance using the features in any method defined above.

A third aspect is a software-implemented tool that enables a loudspeaker to be optimized for a given room or other bounded space, the loudspeaker automatically affecting, modifying or decreasing low frequency peaks associated with interacting sound waves in that bounded space by virtue of being automatically configured using a model of the acoustics of the bounded space.

The software-implemented tool enables the loudspeaker to be optimised for performance using the features in any method defined above.

A fourth aspect is a media streaming platform or system which streams media, such as music and/or video, to networked media output devices, such as smartphones, tablets, home computers, games consoles, home entertainment systems, automotive entertainment systems, and headphones, in which the platform enables the acoustic performance of the loudspeakers in specific output devices to be optimized for a given room or other bounded space, the loudspeaker automatically affecting, modifying or decreasing low frequency peaks associated with interacting sound waves in that bounded space by virtue of being automatically configured using a model of the acoustics of the bounded space.

The media streaming platform or system enables the loudspeaker to be optimised for performance using the features in any method defined above.

### Appendix 2 Detailed Description

One implementation of the invention is a new model based approach to room mode optimisation. The approach employs a technique to reduce the deleterious effects of room response on loudspeaker playback. The method provides effective treatment of sonic artefacts resulting from low frequency room modes (room mode optimisation). The technique is based on knowledge of the physical principles of sound propagation within bounded spaces and does not employ microphone measurements to drive the optimisation. Instead it uses measurements of the room dimensions, loudspeaker and listener locations to provide the necessary optimisation filters.

Key features of an implementation include the following:
Room mode optimisation based on modelled room response using a modal summation technique for source to receiver transfer function estimation.
   Model employs all low frequency sources in the loudspeaker(s) (including subwoofers) with their respective locations within the bounded acoustic space.
   Each low frequency source is modelled using the appropriate frequency response as prescribed by the crossover filters designed into the loudspeaker.
   Location of the low frequency sources and their prescribed crossover responses is adaptive with information being drawn from the cloud appropriate to the loudspeaker being installed.
   The model ensures that only modal peaks present in the vicinity of the listening position are treated.
   Limits corrective filtering to below 80 Hz, much lower than suggested by prior art.
Cloud submission and processing.
   The optimisation filters may be calculated locally on a personal computer, or alternatively the room data can be uploaded and optimisation filters calculated in the cloud.
Submission of human adjustments (to derived filters) and room dimensions to the cloud for use in creating predictive models for use in other rooms.
   The filter calculations are based on simple rectangular spaces with typical construction related absorption characteristics. Some human adjustment may be required for non-typical installations. Experience gained from such installations will be shared in the cloud allowing predictive models to be produced based on installer experience.
The method is dynamic: they can be modified and re-applied by the user within the home environment.

### Method for Room Mode Optimisation

The most simple, and musically least destructive, approach to reducing the deleterious effects of room modes is to apply sharp notch filters at frequencies corresponding to the natural modes of the room. This simplistic approach can cause problems if not carefully implemented. Consider the first room mode across the listening room, whose pressure distribution will exhibit high pressure on one side of the room, and low pressure on the opposite wall. If the loudspeakers are placed symmetrically (approximately) across the room; the left hand speaker will excite the room mode with positive pressure one the left side of the room while the right hand loudspeaker does the same on the opposite side, effectively cancelling the fundamental mode across the room. In the listening position there will be little or no deleterious influence from this room mode. For higher order modes there may be no modal accentuation at the listening position, so applying a notch at this frequency would introduce an audible error.

To correctly treat room modes it is necessary to examine the source (loudspeaker) to receiver (listener) transfer function in the presence of modes. This is achieved through use of a modal summation approach, whereby the coupling between all low frequency sources and receiver, and the modal structure of the room are assessed and a transfer function is derived. The method is outlined below:

### Calculation of Mode Frequencies and Modal Distribution

In general, the resonant frequencies of a simple cuboid room are given by the Rayleigh¹ equation:

$$f ( {n}_{x} , {n}_{y} , {n}_{z} ) = \frac{c}{2} \sqrt{{( \frac{{n}_{x}}{{L}_{x}} )}^{2} + {( \frac{{n}_{y}}{{L}_{y}} )}^{2} + {( \frac{{n}_{z}}{{L}_{z}} )}^{2}} \qquad Eq . 1$$

Where Lₓ, L_{y}, and L_{z} are the length width and height of the room respectively,
n is the natural mode order (positive integers including zero),
   and c is the velocity of sound in the medium (344 ms⁻¹ in air).

The pressure at any location in a simple cuboid room for a given natural mode is proportional to product of three cosine functions, as shown below:

$$\vert p \vert ∝ cos \frac{{n}_{x} π x}{{L}_{x}} cos \frac{{n}_{y} π y}{{L}_{y}} cos \frac{{n}_{z} π z}{{L}_{z}} \qquad Eq . 2$$

### Calculating the Reverberant Sound Field

The instantaneous reverberant sound pressure level, pᵣ, at a receiving point R(x,y,z) from a source at S(x₀, y₀, z₀) is given by:

$${p}_{r} = \frac{ρ {c}^{2} {Q}_{0}}{V} {e}^{- jω t} {\sum }_{N} \frac{{ɛ}_{nx} {ɛ}_{ny} {ɛ}_{nz} {ψ}_{N} ( S ) {ψ}_{N} ( R )}{2 {ω}_{N} \frac{{k}_{N}}{ω} + j ( \frac{{ω}_{N}^{2}}{ω} - ω )} \qquad Eq . 3$$

Where Q₀ is the volume velocity of the source,
ρ is the density of the medium (1.206 in air),
c is the velocity of sound in the medium (344 ms⁻¹ in air),
V is the room volume,
ω is the angular frequency at which the mode contribution is required,
   and ω_{N} is the natural mode angular frequency.

The terms εₙ are scaling factors depending on the order of the mode, being 1 for zero order modes and 2 for all other modes:

ε₀=1,ε₁=ε₂=ε₃= . . . =2 Eq. 4

The damping term, k_{N}, can be calculated from the mode orders and the mean surface absorption coefficients. The general form of this involves a great deal of calculation relating to the mean effective pressure for different surfaces, depending on the mode order in the appropriate direction. It is simplified for rectangular rooms with three-way uniform absorption distribution to:

$${k}_{N} = \frac{c}{8 V} \cdot \frac{( {ɛ}_{nx} {a}_{x} + {ɛ}_{ny} {a}_{y} + {ɛ}_{nz} {a}_{z} )}{2} \qquad Eq . 5$$

Where aₓ represents the total surface absorption of the room boundaries perpendicular to the x-axis, approximated by:

aₓ=Sₓα̅ₓEq. 6

Where Sₓ is the total surface area of the room boundaries perpendicular to the x-axis,

and αₓ is the average absorption coefficient of the room boundaries perpendicular to the x-axis.

The functions, ψ(x,y,z), are the three-dimensional cosine functions representing the mode spatial distributions, as defined in equation 10. For the source position:

$${ψ}_{N} ( S ) = cos \frac{{n}_{x} π {x}_{S}}{{L}_{x}} cos \frac{{n}_{y} π {y}_{S}}{{L}_{y}} cos \frac{{n}_{z} π {z}_{S}}{{L}_{z}} \qquad Eq . 7$$

Similarly, for the receiver position:

$${ψ}_{N} ( R ) = cos \frac{{n}_{x} π {x}_{R}}{{L}_{x}} cos \frac{{n}_{y} π {y}_{R}}{{L}_{y}} cos \frac{{n}_{z} π {z}_{R}}{{L}_{z}} \qquad Eq . 8$$

Where n is the mode order,
L is the room dimension
   and x, y, z refer to the principle coordinate axes.

It will be shown later that the normal type of loudspeaker produces a volume velocity inversely proportional to frequency, at least at lower frequencies where the drive units are mass controlled. Thus, the term Q₀ in the above can be replaced by 1/ω times some constant of proportionality. Assuming that this constant is unity, splitting the function into real and imaginary parts (for computational convenience) and converting to r.m.s. gives:

$${p}_{r , rms} \approx \frac{ρ {c}^{2}}{\sqrt{2} ω V} {\sum }_{N} ( \frac{ab}{( {b}^{2} + {c}^{2} )} - j \frac{ac}{( {b}^{2} + {c}^{2} )} ) \qquad Eq . 9$$

Where a=εₙₓε_{ny}ε_{nz}ψ(S)ψ(R),

$$b = \frac{2 {ω}_{N} {k}_{N}}{ω} , \\ and$$

$$c = \frac{{ω}_{N}^{2}}{ω} - ω .$$

### Calculating the Direct Sound Field

The instantaneous direct sound pressure level, p_{d}, at a radial distance r from an omni-directional source of volume velocity Q₀ is given by:

$${p}_{d} \approx \frac{ρ}{4 π r} {Q}^{′} ( t - \frac{r}{c} ) \qquad Eq . 10$$

Where the function Q′(z) represents:

$${Q}^{′} ( z ) = \frac{d ( Q ( z ) )}{d z} \qquad Eq . 11$$

Substituting the usual expression for a phase shifted sinusoidal function:

$$Q ( t ) = {Q}_{0} {e}^{- jω ( t - \frac{r}{c} )} \qquad Eq . 12$$

Gives:

$${p}_{d} \approx - jω \frac{ρ}{4 π r} {Q}_{0} {e}^{jω ( \frac{r}{c} - t )} \qquad Eq . 13$$

Converting to r.m.s. and extracting real and imaginary terms gives:

$${p}_{d , rms} \approx \frac{ρ}{4 π r \sqrt{2}} ( sin \frac{ω r}{c} - j cos \frac{ω r}{c} ) \qquad Eq . 14$$

### Calculating the Total Sound Field

The total mean sound pressure level, pₜ, is given by the sum:

pₜ=pᵣ+p_{d} Eq. 15

The depth of the required filter notches are defined by the difference in gain between the direct pressure response and the ‘summed’ (direct and room) response. The quality factor of each notch is defined mathematically within the simulation. It should be noted that the centre frequency, depth and quality factor of each filter can be adjusted by the installer to accommodate for deviation between the simulation and the real room.

### Improving the Accuracy of the Model

To further improve accuracy each low frequency source is band limited as prescribed by the crossover functions used in the product being simulated. In the case of one implementation, the loudspeaker the source to receiver modal summation is performed using six sources, the two servo bass drivers and the upper bass driver of each loudspeaker. The crossover filter shapes are applied to each of the sources in the simulation ensuring accurate modal coupling for the distributed sources of the loudspeakers in the model.

Treatment of room modes above 80 Hz has been found to be detrimental to the musical quality of the optimised system. Applying sharp notches in the vocal and fundamental musical frequency range introduce magnitude and phase distortion to the first arrival (direct sound from loudspeaker to listener). These forms of distortion are clearly audible and reduce the musical qualities of the playback system, affecting both perceived tonal balance and localisation cues. For this reason the proposed room mode optimisation method limits the application of corrective notches to 80 Hz and below. Sound below 80 Hz offer no directional cues for the human listener. The wavelengths of low frequencies are so long that the relatively small path differences between reception at each ear allow for no psychoacoustic perception of directivity. Furthermore the human ear is less able to distinguish first arrival from room support at such low frequencies, the Haas effect is dominated by midrange and high frequency content.

A further reason for the low frequency limit for room mode correction must be drawn from the accuracy of any source to receiver model employed. Above 100 Hz the validity of the simulation must come into question, chaotic effects in real rooms resulting from placement of furniture and the influence of non-regular walls will introduce reactive absorption. These influences tend to smooth the room response above 100 Hz and would result in a less ‘peaky’ measured response than is suggested by the simulation.

Use of Human Derived Filters for Predictive Development.

The basic form of the room optimisation filter calculation makes the assumption of a simple rectangular room. This assumption places a limit on the accuracy of the filters produced when applied to real world rooms. Quite often real rooms may either only loosely adhere to, or be very dissimilar to, the simple rectangular room employed in the optimisation filter generation simulation. Real rooms may have a bay window or chimney breast which breaks the fundamental rectangular shape of the room. Also many real rooms are simply not rectangular, but may be ‘L-shaped’ or still more irregular. Ceiling heights may also vary within a room. In these instances some user manipulation of the filters may be required.

The facility is available for users to ‘upload’ a model of their room along with their final optimisation filters to the cloud. These models and filter sets can then be employed to derive predictive filter sets for other similarly irregular rooms.

### Cloud Submission and Processing

It is possible, where local processing power is limited or unavailable (e.g. on a mobile or tablet device), to provide the pertinent information regarding the room dimensions, loudspeaker positions and listener location to an app. The app then uploads the room model to the cloud where processing can be performed. The result of the cloud processing (the room optimisation filter) is then returned to the local app for application to the processing engine.

### The Methods are Dynamic

The filters applied are not dependant on acoustic measurement or application by trained installer; instead they are dynamic and configurable by the user. This allows flexibility to the optimisation system and provides the user with the opportunity to change the level of optimisation to suit their needs. The user can move the system subsequent to set up (for example to a new room, or to accommodate new furnishings) and re-apply the room optimisation filters to reflect changes.

### Appendix 2: Numbered and Claimed Concepts

1. A method for optimizing the performance of a loudspeaker in a given room or other bounded space to compensate for sonic artefacts comprising the step of (a) automatically modelling the acoustics of the bounded space and then (b) automatically affecting or modifying the signal in order to mitigate aberrations associated with room resonances, using a corrective optimisation filter automatically generated with that modelling.

2. The method of claim 1 in which low frequency peaks resulting from room resonances are mitigated by modifying the signal sent to a loudspeaker.

3. The method of claim 1 in which the corrective optimization filter that automatically affects, modifies or decreases the low frequency peaks is generated using a loudspeaker-to-listener transfer function in the presence of room modes.

4. The method of claim 3, in which the transfer function is derived from the coupling between low frequency sources and the listener and the modal structure of the room.

5. The method of any preceding Claim in which a modal summation approach is used, whereby the coupling between low frequency sources and the listener and the modal structure of the room are assessed.

6. The method of any preceding Claim in which room modes above the frequency at which the precedence effect, as defined by Haas, and that allow human determination of the direct sound separately from the room response, are deliberately not treated.

7. The method of claim 6 in which room modes above approximately 80 Hz are deliberately not treated.

8. The method of any preceding Claim in which the corrective optimization filter is derived by modeling the low frequency sources in a loudspeaker and their location(s) within the bounded acoustic space.

9. The method of any preceding Claim in which the bounded acoustic space is assumed to have a generalized acoustic characteristic and/or the acoustic behavior of the boundaries are further defined by their absorption/transmission characteristics.

10. The method of any preceding Claim in which the corrective optimization filter substantially treats only those modal peaks that are in the vicinity of a listening position.

11. The method of any preceding Claim in which modelling each low frequency sources uses the frequency response prescribed by a digital crossover filter for that source.

12. The method of any preceding Claim in which the basic shape of the room is assumed to be rectangular and a user can alter the corrective optimization filter to take into account different room shapes.

13. The method of any preceding Claim in which the corrective optimization filter is calculated locally, such as in the music system that includes the loudspeaker.

14. The method of any preceding Claim in which the corrective optimization filter is calculated remotely at a server, such as in the cloud, using room data that is sent to the server.

15. The method of any preceding Claim in which the remote server stores the frequency response prescribed by the digital crossover filter for each source and uses that response data when calculating a filter.

16. The method of any preceding Claim in which the filter and associated room model/dimensions for one room are re-used in creating filters for different rooms.

17. The method of any preceding Claim in which the filter can be dynamically modified and re-applied by an end-user.

18. The method of any preceding Claim in which user-modified filter settings and associated room dimensions are collated and processed to provide feedback to both the user and the predictive model.

19. The method of any preceding Claim in which user adjustments, such as user-modified filter settings that differ from model predicted values are collated according to room dimensions and this information is then used to (i) suggest settings for non-rectangular rooms, and/or (ii) provide alternative settings for rectangular rooms that may improve sound quality, and/or (iii) provide feedback to the model such that it can learn and provide better compensation over a wider range of room shapes.

20. The method of any preceding Claim which enables the quality of music reproduction to be optimized, taking into account the acoustic properties of furnishings in the room or other environment.

21. The method of any preceding Claim which enables the quality of music reproduction to be optimized, taking into account the required position of the speakers in the room or other environment.

22. The method of any preceding Claim which does not require any microphones and so the acoustics are modeled and not measured.

23. A loudspeaker optimized for a given room or other bounded space, the loudspeaker automatically affecting, modifying or decreasing low frequency peaks associated with interacting sound waves in that bounded space by virtue of being automatically configured using a corrective optimisation filter automatically generated using a model of the acoustics of the bounded space.

24. The loudspeaker defined in claim 23 optimised for performance using the method of any preceding claim 1-22.

25. A media output device, such as a smartphone, tablet, home computer, games console, home entertainment system, automotive entertainment system, or headphones, comprising at least one loudspeaker optimized for a given room or other bounded space, the loudspeaker automatically affecting, modifying or decreasing low frequency peaks associated with interacting sound waves in that bounded space by virtue of being automatically configured using a corrective optimisation filter automatically generated with a model of the acoustics of the bounded space.

26. The media output device of claim 25 in which the loudspeaker is optimised for performance using the method of any preceding claim 1-22.

27. A software-implemented tool that enables a loudspeaker to be optimized for a given room or other bounded space, the loudspeaker automatically affecting, modifying or decreasing low frequency peaks associated with interacting sound waves in that bounded space by virtue of being automatically configured using a corrective optimisation filter automatically generated with a model of the acoustics of the bounded space.

28. The software-implemented tool of claim 27 in which the loudspeaker is optimised using the method of any preceding claim 1-22.

29. A media streaming platform or system which streams media, such as music and/or video, to networked media output devices, such as smartphones, tablets, home computers, games consoles, home entertainment systems, automotive entertainment systems, and headphones, in which the platform enables the acoustic performance of the loudspeakers in specific output devices to be optimized for a given room or other bounded space, the loudspeaker automatically affecting, modifying or decreasing low frequency peaks associated with interacting sound waves in that bounded space by virtue of being automatically configured using a corrective optimisation filter automatically generated with a model of the acoustics of the bounded space.

30. The media streaming platform or system of claim 29 in which the loudspeaker is optimised using the method of any preceding claim 1-22.

### APPENDIX 2: Abstract

A method for optimizing the performance of a loudspeaker in a given room or other bounded space to compensate for sonic artefacts comprising the step of (a) automatically modelling the acoustics of the bounded space and then (b) automatically affecting, modifying or decreasing the low frequency peaks associated with interacting sound waves, using that modelling. A corrective optimization filter that automatically affects, modifies or decreases the low frequency peaks is generated using a loudspeaker-to-listener transfer function in the presence of room modes. The transfer function is derived from the coupling between low frequency sources and the listener and the modal structure of the room.

### Appendix 3 Boundary Optimisation

This Appendix 3 describes an additional concept.

### Method of Optimizing the Performance of a Loudspeaker Using Boundary Optimisation

### Appendix 3: Background

### 1. Field

The concept relates to a method of optimizing the performance of a loudspeaker in a given room or other environment. It solves the problem of negative effects of room boundaries on loudspeaker performance using boundary optimisation techniques.

### 2. Description of the Prior Art

### Boundary Optimisation

The primary motivation for boundary optimisation is fuelled by the desire by many audio system owners to have their loudspeaker systems closer to bounding walls than would be ideal for best sonic performance. It is quite common for larger loudspeakers to perform better when placed a good distance from bounding walls, especially the wall immediately behind the loudspeaker. It is equally typical for owners not to want large loudspeakers placed well into the room for cosmetic reasons.

The frequency response of a loudspeaker system depends on the acoustic load presented to the loudspeaker, in much the same way that the output from an amplifier depends on the load impedance. While an amplifier drives an electrical load specified in ohms, a loudspeaker drives an acoustic load typically specified in ‘solid angle’ or steradians.

As a loudspeaker drive unit is driven it produces a fixed volume velocity (the surface area of the driver multiplied by the excursion), which naturally spreads in all directions. When the space seen by the loudspeaker is limited and the volume velocity is kept constant the energy density (intensity) in the limited radiation space increases. A point source in free space will radiate into 4π steradians, or full space. If the point source were mounted on an infinite baffle (a wall extending to infinite in all directions) it would be radiating into 2π steradians, or half space. If the source were mounted at the intersection of two infinite perpendicular planes the load would be IC steradians, or quarter space. Finally, if the source was placed at the intersection of three infinite planes, such as the corner of a room, the load presented would be π/2 steradians, or eighth space. Each halving of the radiation space constitutes an increase of 6 dB in measured sound pressure level, or an increase of 3 dB in sound power.

The most commonly specified loudspeaker load is half space, though this only really applies to midrange and higher frequencies. While commonly all of the loudspeaker drive units are mounted on a baffle only the short wavelengths emitted from the upper midrange and high frequency units see the baffle as a near infinite plane and are presented with an effective 2a steradians load. As frequency decreases and the corresponding radiated wavelength increases the baffle ceases to be seen as near infinite and the loudspeaker sees a load approaching full space, or 4π steradians. This transition from half space to full space loading is commonly called the ‘baffle step effect’, and results in a 6 dB loss of bass pressure with respect to midrange and high frequencies. At even lower frequencies, typically below 100 Hz, the wavelength of the radiated sound is long enough that the walls of the listening room begin to load the system in a complex way that will be less than half space and at very low frequencies may achieve eighth space. It is the low and very low frequency boundary interaction which is optimised by the proposed system.

Existing systems (prior art) which seek to alleviate the influence of local boundaries on loudspeaker playback assume the loudspeaker is moved from free space (the absence of any boundaries) to a location coincident with a boundary or boundaries. Filtering in these systems tend to the form of a low frequency shelving filter to reduce bass output when placed in the proximity of a boundary. The filter becomes active at some small amount below the baffle transition of the loudspeaker system, typically around 200-300 Hz.

Thorough analysis of the problem shows that within any real room the lowest frequencies will always be influenced by local boundaries and therefore should not receive any subsequent filtering for correction of boundary influence. Instead there will be a narrow band of frequencies, whose wavelengths lie between those at baffle transition and those for which the room boundaries appear as local, which will require attention for correct boundary optimisation. The calculation of the boundary effect filter used by one example of the proposed system treats this narrow band of frequencies.

Problems with Microphone Based Optimisation Techniques

Most microphone based room correction techniques rely on a number of assumptions regarding a desired ‘target’ response at the listening position. Most commonly this target is a flat frequency response, irrespective of the original designed frequency response of the loudspeaker system being corrected.

Often microphone based correction algorithms will apply both cut and boost to signals to correct the in-room response of a loudspeaker system to the desired target response. The application of boosted frequencies can cause the loudspeakers to be overdriven resulting in physical damage to the loudspeaker drive units either by excess mechanical movement or damage to the electrical parts through clipped amplifier signals. Typically an active loudspeaker, whose amplification is built into the loudspeaker to comprise a complete playback system, is designed to ensure that the dynamic range of the loudspeaker drive units match the dynamic range of the amplifiers. If a room correction regime applies boost to an active loudspeaker system there is an increased risk of overdriving and damaging the system.

Microphone correction systems often result in a sweet spot where the sound is adequately corrected to the desired target response. Outside of this (often very) small area the resulting sound may be left less ideal than it was prior to correction.

Where microphone measurements are provided to an end user for further human correction too often little can be deduced regarding room effects from the measured response. Aberrations in the measured pressure response may be caused by a number of factors including; room acoustic effects, constructive and destructive interference from the multiple loudspeakers and their individual drive units, inappropriate or un-calibrated hardware (both source and receiver), physical characteristics of the loudspeaker (baffle step or diffraction effects). When a lay user appraises the measured response there is little to inform him of whether observed aberrations are due to room interaction, characteristics of the loudspeaker system, or artefacts of the measurement. As a result corrective filtering is often applied in error, resulting in poor system response and the potential of damage.

### Appendix 3: Summary of the Concept

The concept is a method of optimizing the performance of a loudspeaker in a given room or other environment in which a corrective optimisation filter is used so that the loudspeaker emulates the sound that would be generated by a loudspeaker at the ideal location(s), but when in a secondary position.

Optional features in an implementation of the concept include any one or more of the following:
the corrective optimisation filter is customised or specific to that room or environment
the secondary position is the normal position or location the end-user intends to place the loudspeaker at, and this normal position or location may be anywhere in the room or environment.
the ideal location(s) are noted and the normal positions are also noted; the optimization filter is then automatically generated using the distances from the loudspeaker to one or more room boundaries in both the ideal and normal locations.
a software-implemented system uses the distances from the loudspeaker(s) to the room boundaries in both the ideal location(s) and also the normal location(s) to produce the corrective optimization filter.
the ideal location(s) are determined by a human, such as an installer or the end-user and those locations noted; the loudspeakers are moved to their likely normal locations(s) and those locations noted.
the corrective optimization filter compensates for the real position of the loudspeaker(s) in relation to local bounding planes, such as two or more local bounding planes.
the optimization filter modifies the signal level sent to the drive unit(s) of the loudspeaker at different frequencies if the loudspeaker's real position relative to any local boundary differs from its ideal location or position.
the frequencies lie between those at baffle transition and those for which the room boundaries appear as local.
the optimization filter is calculated assuming either an idealized ‘point source’, or a distributed source defined by the positions and frequency responses of the radiating elements of a given loudspeaker.
the corrective optimization filter is calculated locally, such as in a computer operated by an installer or end-user, or in the music system that the loudspeaker is a part of.
the corrective optimization filter is calculated remotely at a server, such as in the cloud, using room data that is sent to the server.
the corrective optimization filter and associated room model/dimensions for one room are re-used in creating corrective optimization filters for different rooms.
the corrective optimization filter can be dynamically modified and re-applied by an end-user.
the boundary compensation filter is a digital crossover filter.
the method does not require microphones and so the acoustics of the room or environment are modelled and not measured.
the influence or 1, 2, 3, 4, 5, 6 or more boundaries are modelled.

Other aspects include the following:

A first aspect is a loudspeaker optimized for a given room or other environment in which a corrective optimisation filter is used so that the loudspeaker emulates the sound that would be generated by a loudspeaker at the ideal location(s), but when in a secondary position.

The loudspeaker may be optimised using any one or more of the features defined above.

A second aspect is a media output device, such as a smartphone, tablet, home computer, games console, home entertainment system, automotive entertainment system, or headphones, comprising at least one loudspeaker optimized for a given room or other environment, in which a corrective optimisation filter is used so that the loudspeaker emulates the sound that would be generated by a loudspeaker at the ideal location(s), but when in a secondary position.

The media output device may be optimised using any one or more of the features defined above.

A third aspect is a software-implemented tool that enables a loudspeaker to be optimized for a given room or other environment in which a corrective optimisation filter is used so that the loudspeaker emulates the sound that would be generated by a loudspeaker at the ideal location(s), but when in a secondary position.

The software-implemented tool may optimise a loudspeaker using any one or more of the features defined above.

A fourth aspect is a media streaming platform or system which streams media, such as music and/or video, to networked media output devices, such as smartphones, tablets, home computers, games consoles, home entertainment systems, automotive entertainment systems, and headphones, in which the platform enables the acoustic performance of the loudspeakers in specific output devices to be optimized for a given room or other environment and in which a corrective optimisation filter is used so that the loudspeaker emulates the sound that would be generated by a loudspeaker at the ideal location(s), but when in a secondary position.

The media streaming platform or system may optimise a loudspeaker using any one or more of the features defined above.

A fifth aspect is a method of capturing characteristics of a room or other environment, comprising the steps of providing a user with an application or interface that enables the user to define or otherwise capture and then upload a model of their room or environment to a remote server that is programmed to optimise the performance of audio equipment such as loudspeakers in that room or environment using that model.

The model may include one or more of the following parameters of the room or environment: shape, dimensions, wall construction, altitude, furniture, curtains, floor coverings, desired loudspeaker(s) location(s), ideal loudspeaker(s) location(s), anything else that affects acoustic performance. The server may optimise loudspeaker performance using any one or more of the features defined above.

### Appendix 3: Detailed Description

An implementation of the invention is a new listener focussed approach to room boundary optimisation. The approach employs a new technique to reduce the deleterious effects of room boundaries on loudspeaker playback. This provides effective treatment of sonic artefacts resulting from poor placement of the loudspeakers within the room. The technique is based on knowledge of the physical principles of sound propagation within bounded spaces and does not employ microphone measurements to drive the optimisation. Instead they use measurements of the room dimensions and loudspeaker locations to provide the necessary optimisation filters.

Key features of an implementation include the following:
3. Emulation of the human determined ideal loudspeaker placement within a room when the loudspeakers are placed in less than optimal location.
   Produces a corrective filter which when applied to loudspeakers placed in less than optimal locations will return the sound quality to that observed when the loudspeakers were ideally placed.
   Ideal placement is user/installer determined.
   Non-ideal placement is customer specified.
   Currently operates assuming change of distance to two local bounding planes, but may be extended to six or more planes.
4. Cloud submission and processing.
   The optimisation filters may be calculated locally on a personal computer, or alternatively the room data can be uploaded and optimisation filters calculated in the cloud.
5. Submission of human adjustments (to derived filters) and room dimensions to the cloud for use in creating predictive models for use in other rooms.
   The filter calculations are based on simple rectangular spaces with typical construction related absorption characteristics. Some human adjustment may be required for non-typical installations. Experience gained from such installations will be shared in the cloud allowing predictive models to be produced based on installer experience.

6. The methods are dynamic: they can be modified and re-applied by the user within the home environment.

### Method for Boundary Optimisation

For the proposed boundary compensation to work optimally the loudspeakers must initially be placed in a location which provides the best sonic performance. These locations are defined by the user or installer during system set-up. The locations are noted and the loudspeakers can then be moved to locations more in line with the customers' requirements. The system employs the distances from the loudspeaker to the room boundaries, in both the ideal and practical locations, to produce an optimisation filter which, when the loudspeakers are placed in the practical location, will match the response achieved when the loudspeakers where placed for best sonic performance.

The approach adopted for boundary optimisation provides a very effective means of equalising the loudspeaker when it is moved closer to a room boundary than is ideal. The system will also optimise the loudspeakers when they are placed further from boundaries, and indeed can be used to optimise loudspeakers when a boundary is not present (e.g. when a loudspeaker is a very long distance from a side wall).

### Boundary Influence on Sound Power

The acoustic power output of a source is a function not only of its volume velocity but also of the resistive component of its radiation load. Because the radiation resistance is so small in magnitude in relationship with the other impedances in the system, any change in its magnitude produces a proportional change in the magnitude of the radiated power.

The resistive component of the radiation load is inversely proportional to the solid angle of space into which the acoustic power radiates. If the radiation is into half space, or 2π steradians, the power radiated is twice that which the same source would radiate into full space, or 4π steradians. It must be noted that this simple relationship only holds when the dimensions of the source and the distance to the boundaries are small compared to the wavelength radiated.

Calculation of the influence of boundaries on the pressure response of a source is presented in equations 1 through 3 for one local boundary, two boundaries and three boundaries respectively:

$$\begin{matrix} \frac{W}{{W}_{f}} = 1 + {j}_{0} ( \frac{4 π x}{λ} ) & Eq . 1 \\ \frac{W}{{W}_{f}} = 1 + {j}_{0} ( \frac{4 π x}{λ} ) + {j}_{0} ( \frac{4 π y}{λ} ) + {j}_{0} ( \frac{4 π \sqrt{{x}^{2} + {y}^{2}}}{λ} ) & Eq . 2 \\ \frac{W}{{W}_{f}} = 1 + {j}_{0} ( \frac{4 π x}{λ} ) + {j}_{0} ( \frac{4 π y}{λ} ) + {j}_{0} ( \frac{4 π z}{λ} ) + {j}_{0} ( \frac{4 π \sqrt{{x}^{2} + {y}^{2}}}{λ} ) + {j}_{0} ( \frac{4 π \sqrt{{x}^{2} + {z}^{2}}}{λ} ) + {j}_{0} ( \frac{4 π \sqrt{{y}^{2} + {z}^{2}}}{λ} ) + {j}_{0} ( \frac{4 π \sqrt{{x}^{2} + {y}^{2} + {z}^{2}}}{λ} ) & Eq . 3\end{matrix}$$

Where W is the power radiated by a source located at (x,y,z)/λ,
W_{f} is the power that would be radiated by the source in 4π steradians,
λ is the wavelength of sound
x, y, z specify the source location relative to the boundary(ies)
   and j₀(a)=sin(a)/a is the spherical Bessel function.

The process can easily be extended to include the influence of all six boundaries of a regular rectangular room. In the current implementation of room optimisation the two boundary approach is adopted. This follows the assumption that the distance from the loudspeaker to the floor and ceiling will not change following repositioning of the loudspeakers. The two walls more distant from the loudspeaker under consideration and the floor and ceiling are ignored but may be included in later filter calculations.

To specify the boundary compensation filter (ΔP) we calculate the boundary gain of the loudspeaker in the reference location (using equation 2) and divide by the non-ideal boundary gain, finally converting the result to power.

$$Δ P = 10 \cdot log ( \frac{\begin{matrix}1 + {j}_{0} ( \frac{4 π {D}_{TD\_RW}}{λ} ) + {j}_{0} ( \frac{4 π {D}_{TD\_SW}}{λ} ) + \\ {j}_{0} ( \frac{4 π \sqrt{{D}_{TD\_RW}^{2} + {D}_{TD\_SW}^{2}}}{λ} )\end{matrix}}{1 + {j}_{0} ( \frac{4 π {D}_{RW}}{λ} ) + {j}_{0} ( \frac{4 π {D}_{SW}}{λ} ) + {j}_{0} ( \frac{4 π \sqrt{{D}_{RW}^{2} + {D}_{SW}^{2}}}{λ} )} ) \qquad Eq . 4$$

where D_{TD}_{_}_{RW} and D_{TD}_{_}_{SW} are the distances from the rear and side walls in the loudspeakers' ideal sonic performance placement.
D_{RW} and D_{SW} are the distances from the rear and side walls as dictated by the customer.
   and λ is the wavelength of sound in air at a given frequency.

The resulting boundary compensation filter is then approximated with one or more parametric bell filters to provide the final boundary optimisation filter. The simplification provides a filter solution which introduces less phase distortion to the music signal when applying the optimisation filter, whilst maintaining the gross equalisation required for correcting the change in the loudspeakers boundary conditions.

This simplification of the calculated correction filter ensures that for any movement of the speaker closer to a boundary the optimisation filter will reduce the signal level, preserving the gain structure of the loudspeaker system and limiting the risk of damage through overdriving the system.

When a loudspeaker is moved relative to one or more boundaries, to a location other than that which was found to be optimal for best sonic performance, the optimisation filter may provide either boost or cut to the signal. Increases in low frequency power output resulting from changes to the boundary support for a speaker result in masking of higher frequencies. In this instance the algorithm may choose to either reduce the low frequency content as appropriate, or increase the power output at those higher frequencies where masking is taking place. Any boost which may be applied by the algorithm at substantially low frequency (typically below 100 Hz) is reduced by a factor of two in order to reduce the likelihood of damage to the playback system while still providing adequate optimisation to alleviate the influence of the boundary. Typically low frequency boost is required when the loudspeaker is moved further from a boundary than was found to be optimal for sonic performance. It should be noted that it is uncommon for a user to have a practical location of the loudspeaker which is further into the room than was found for best sonic performance.

### Use of Human Derived Filters for Predictive Development.

The basic form of the boundary optimisation filter calculation makes the assumption of a simple rectangular room. This assumption places a limit on the accuracy of the filters produced when applied to real world rooms. Quite often real rooms may either only loosely adhere to, or be very dissimilar to, the simple rectangular room employed in the optimisation filter generation simulation. Real rooms may have a bay window or chimney breast which breaks the fundamental rectangular shape of the room. Also many real rooms are simply not rectangular, but may be ‘L-shaped’ or still more irregular. Ceiling heights may also vary within a room. In these instances some user manipulation of the filters may be required.

The facility is available for users to ‘upload’ a model of their room (shape, dimensions, wall construction, altitude, furniture, curtains, floor coverings, anything else that affects acoustic performance) along with their final optimisation filters to the cloud. These models and filter sets can then be employed to derive predictive filter sets for other similarly irregular rooms.

### Cloud Submission and Processing

It is possible, where local processing power is limited or unavailable (e.g. on a mobile or tablet device), to provide the pertinent information regarding the room dimensions, loudspeaker positions and listener location to an app. The app then uploads the room model to the cloud where processing can be performed. The result of the cloud processing (the boundary compensation filter) is then returned to the local app for application to the processing engine.

### The Methods are Dynamic

The filters applied are not dependant on acoustic measurement or application by trained installer; instead they are dynamic and configurable by the user. This allows flexibility to the optimisation system and provides the user with the opportunity to change the level of optimisation to suit their needs. The user can move the system subsequent to set up (for example to a new room, or to accommodate new furnishings) and re-apply the boundary compensation filters to reflect changes.

### Appendix 3: Numbered and Claimed Concepts

1. Method of optimizing the performance of a loudspeaker in a given room or other environment in which a corrective optimisation filter is used so that the loudspeaker emulates the sound that would be generated by a loudspeaker at the ideal location(s), but when in a secondary position.

2. The method of claim 1, in which the corrective optimisation filter is customised or specific to that room or environment.

3. The method of claim 1 or 2, in which the secondary position is the normal position or location the end-user intends to place the loudspeaker at, and this normal position or location may be anywhere in the room or environment.

4. The method of any preceding Claim, in which the ideal location(s) are noted and the normal positions are also noted; the optimization filter is then automatically generated using the distances from the loudspeaker to one or more room boundaries in both the ideal and normal locations

5. The method of claim 4, in which a software-implemented system uses the distances from the loudspeaker(s) to the room boundaries in both the ideal location(s) and also the normal location(s) to produce the corrective optimization filter.

6. The method of any preceding Claim, in which the ideal location(s) are determined by a human, such as an installer or the end-user and those locations noted; the loudspeakers are moved to their likely normal locations(s) and those locations noted.

7. The method of any preceding Claim, in which the corrective optimization filter compensates for the real position of the loudspeaker(s) in relation to local bounding planes, such as two or more local bounding planes.

8. The method of any preceding Claim, in which the optimization filter modifies the signal level sent to the drive unit(s) of the loudspeaker at different frequencies if the loudspeaker's real position relative to any local boundary differs from its ideal position.

9. The method of claim 8, in which the frequencies lie between those at baffle transition and those for which the room boundaries appear as local.

10. The method of any preceding Claim, in which the optimization filter is calculated assuming either an idealized ‘point source’, or a distributed source defined by the positions and frequency responses of the radiating elements of a given loudspeaker.

11. The method of any preceding Claim, in which the corrective optimization filter is calculated locally, such as in a computer operated by an installer or end-user, or in the music system that the loudspeaker is a part of.

12. The method of any preceding Claim, in which the corrective optimization filter is calculated remotely at a server, such as in the cloud, using room data that is sent to the server.

13. The method of any preceding Claim, in which the corrective optimization filter and associated room model/dimensions for one room are re-used in creating corrective optimization filters for different rooms.

14. The method of any preceding Claim, in which the corrective optimization filter can be dynamically modified and re-applied by an end-user.

15. The method of any preceding Claim, in which the boundary compensation filter is a digital crossover filter.

16. The method of any preceding Claim, in which the method does not require microphones and so the acoustics of the room or environment are modelled and not measured.

17. The method of any preceding Claim, in which the influence or 1, 2, 3, 4, 5, 6 or more boundaries are modelled.

18. A loudspeaker optimized for a given room or other environment in which a corrective optimisation filter is used so that the loudspeaker emulates the sound that would be generated by a loudspeaker at the ideal location(s), but when in a secondary position.

19. The loudspeaker of claim 18, optimised using the method of any preceding claim 1-17.

20. A media output device, such as a smartphone, tablet, home computer, games console, home entertainment system, automotive entertainment system, or headphones, comprising at least one loudspeaker optimized for a given room or other environment, in which a corrective optimisation filter is used so that the loudspeaker emulates the sound that would be generated by a loudspeaker at the ideal location(s), but when in a secondary position.

21. The media output device of claim 20, optimised using the method of any preceding claim 1-17.

22. A software-implemented tool that enables a loudspeaker to be optimized for a given room or other environment in which a corrective optimisation filter is used so that the loudspeaker emulates the sound that would be generated by a loudspeaker at the ideal location(s), but when in a secondary position.

23. The software-implemented tool of claim 22, which optimises a loudspeaker using the method of any preceding claim 1-17.

24. A media streaming platform or system which streams media, such as music and/or video, to networked media output devices, such as smartphones, tablets, home computers, games consoles, home entertainment systems, automotive entertainment systems, and headphones, in which the platform enables the acoustic performance of the loudspeakers in specific output devices to be optimized for a given room or other environment and in which a corrective optimisation filter is used so that the loudspeaker emulates the sound that would be generated by a loudspeaker at the ideal location(s), but when in a secondary position.

25. The media streaming platform or system of claim 24, which optimises a loudspeaker using the method of any preceding claim 1-17.

26. A method of capturing characteristics of a room or other environment, comprising the steps of providing a user with an application or interface that enables the user to define or otherwise capture and then upload a model of their room or environment to a remote server that is programmed to optimise the performance of audio equipment such as loudspeakers in that room or environment using that model.

27. The method of claim 26 in which the model includes one or more of the following parameters of the room or environment: shape, dimensions, wall construction, altitude, furniture, curtains, floor coverings, desired loudspeaker(s) location(s), ideal loudspeaker(s) location(s), and anything else that affects acoustic performance.

### Appendix 3: Abstract

Method of optimizing the performance of a loudspeaker in a given room or other environment in which a corrective optimisation filter is used so that the loudspeaker emulates the sound that would be generated by a loudspeaker at the ideal location(s), but when in a secondary position. The ideal location(s) are noted and the normal positions are also noted; the optimization filter is then automatically generated using the distances from the loudspeaker to the room boundaries in both the ideal and normal locations.

1. A method for reducing loudspeaker magnitude and/or phase distortion, in which one or more filters pertaining to one or more drive units is automatically generated or modified based on the response of each specific drive unit and in which improved drive unit model or measurement data is stored remotely and sent over the internet to update the filter or filters for a specific drive unit.

2. The method of claim 1, in which the drive unit response is determined by modelling the drive unit.

3. The method of claim 1, in which the drive unit response is determined by electro-mechanical modelling of the drive unit.

4. The method of claim 3, in which the electro-mechanical modelling is enhanced by electro-mechanical measurement of a specific drive unit such that the resulting filter becomes specific to that drive unit.

5. The method of claim 3 in which the electro-mechanical modelling of the drive unit is defined using any one or more of the parameters fₛ, Q_{TS}, R_{E}, L_{c} or L_{VC}.

6. The method of claim 2, in which the drive unit response is determined by acoustic modelling of the drive unit.

7. The method of claim 2, in which the modelling incorporates any electronic passive filtering in front of the drive unit.

8. The method of claim 3, in which the electro-mechanical modelling is enhanced by electro-mechanical measurement of the passive filtering in front of each drive unit.

9. The method of claim 2, in which the modelling is enhanced by the use of acoustic measurements of a specific drive unit.

10. The method of claim 2, in which the filter is automatically generated or modified using a software tool or system based on the above modelling and is implemented using a digital filter, such as a FIR filter.

11. The method of claim 1, in which the filter incorporates a band limiting filter, such as a crossover filter, such that the resulting filter exhibits minimal or zero magnitude and/or phase distortion when combined with the drive unit response.

12. The method of claim 1, in which the filter incorporates an equalisation filter such that the resulting filter exhibits minimal or zero magnitude and/or phase distortion when combined with the drive unit response.

13. The method of claim 1, in which the filter is performed prior to a passive crossover such that the filter, when combined with the passive crossover and the drive unit response reduces the magnitude and/or phase distortion of the overall system.

14. The method of claim 1, in which the filter is performed prior to an active crossover such that the filter, when combined with the passive crossover and the drive unit response reduces the magnitude and/or phase distortion of the overall system.

15. The method of claim 2, in which the drive unit model is derived from an electrical impedance measurement.

16. The method of claim 2, in which the drive unit model is enhanced by a sound pressure level measurement.

17. The method of claim 1, in which the filter operates such that the signal sent to each drive unit is delayed such that the instantaneous sound from each of the multiple drive units arrives coincidentally at the listening position.

18-20. (canceled)

21. The method of claim 2 in which, if the drive unit is replaced, then the filter is updated to use the modelling data for the replacement drive unit.

22. (canceled)

23. The method of claim 1 in which the response of a drive unit for the loudspeaker are measured whilst in operation and the filter is regularly or continuously updated, for example in real-time or when the system is not playing, to take into account electro-mechanical variations, for example associated with variations in operating temperature.

24. The method of claim 1 in which volume controls of the loudspeaker are implemented in the digital domain after the filter such that filter precision is maximised.

25. A loudspeaker including one or more filters each pertaining to one or more drive units, in which the filter is automatically generated or modified based on the response of each specific drive unit and in which improved drive unit model or measurement data is stored remotely and sent over the internet to update the filter or filters for a specific drive unit.

26. (canceled)

27. A media output device, such as a smartphone, tablet, home computer, games console, home entertainment system, automotive entertainment system, or headphones, comprising at least one loudspeaker including one or more filters each pertaining to one or more drive units, in which the filter is automatically generated or modified based on the response of each specific drive unit and in which improved drive unit model or measurement data is stored remotely and sent over the internet to update the filter or filters for a specific drive unit.

28. (canceled)

29. A software-implemented tool that enables a loudspeaker to be designed, the loudspeaker including one or more filters each pertaining to one or more drive units, in which the tool or system enables the filter to be automatically generated or modified based on the response of each specific drive unit and in which improved drive unit model or measurement data is stored remotely and sent over the internet to update the filter or filters for a specific drive unit.

30. (canceled)

31. A media streaming platform or system which streams media, such as music and/or video, to networked media output devices, such as smartphones, tablets, home computers, games consoles, home entertainment systems, automotive entertainment systems, and headphones, in which the platform enables the acoustic performance of the loudspeakers in specific output devices to be improved by minimizing their phase distortion, by enabling one or more filters each pertaining to one or more drive units to be automatically generated or modified based on the response of each specific drive unit, or for those filters to be used and in which improved drive unit model or measurement data is stored remotely and sent over the internet to update the filter or filters for a specific drive unit.

32-42. (canceled)
